(19) United States
(12) Patent Application Publication
(10) Pub. No.: US 2026/0076051 A1
(43) Pub. Date: Mar. 12, 2026

(54) SEMICONDUCTOR DEVICE AND METHOD FOR MANUFACTURING SEMICONDUCTOR DEVICE

(71) Applicant: SONY SEMICONDUCTOR SOLUTIONS CORPORATION, KANAGAWA (JP)

(72) Inventors: TAKASHI YAMAZAKI, KANAGAWA (JP); KAZUHIRO TAMURA, KANAGAWA (JP); TOMOKAZU OHCHI, KANAGAWA (JP)

(21) Appl. No.: 19/106,195

(22) PCT Filed: Aug. 9, 2023
(86) PCT No.: PCT/JP2023/029027

§ 371 Date: Feb. 24, 2025

(30) Foreign Application Priority Data
Sep. 1, 2022 (JP) 2022-139289

(51) Int. Cl. H10K 59/131; H10K 59/12; H10K 59/121; H10K 59/127

(52) U.S. Cl. CPC H10K 59/1315; H10K 59/1201; H10K 59/1213; H10K 59/1275

(57) ABSTRACT

A semiconductor device is a semiconductor device including a plurality of pixels each emitting light, the semiconductor device includes a first semiconductor substrate including a transistor of a pixel circuit configured to control light emission of each of the plurality of pixels, a front surface wiring layer provided on a front surface of the first semiconductor substrate, a light emitting element layer provided on a side opposite to the first semiconductor substrate with the front surface wiring layer interposed therebetween, a back surface wiring layer provided on a back surface of the first semiconductor substrate, a second semiconductor substrate including a transistor of a drive circuit configured to drive the pixel circuit, a front surface wiring layer provided on a front surface of the second semiconductor substrate and bonded to the back surface wiring layer of the first semiconductor substrate so as to have electrical contact with the back surface wiring layer of the first semiconductor substrate, and a through-substrate via configured to penetrate the first semiconductor substrate and connect the front surface wiring layer and the back surface wiring layer of the first semiconductor substrate.

### FIELD

The present disclosure relates to a semiconductor device and a method for manufacturing the semiconductor device.

### BACKGROUND

A display device including two semiconductor substrates bonded together is known (refer to, for example, Patent Literature 1).

### CITATION LIST

### Patent Literature

Patent Literature 1: WO 2020/066787 A

Patent Literature 2: JP 6031954 B2

Patent Literature 3: JP 2014-187166 A

Patent Literature 4: WO 2019/087764 A

### SUMMARY

### Technical Problem

In the display device of Patent Literature 1, a via (through-substrate via) penetrating a semiconductor substrate is provided for each pixel. Since many through-substrate vias are provided, a wiring layer region may be limited.

One aspect of the present disclosure is to secure the wiring layer region while providing a through-substrate via.

### Solution to Problem

A semiconductor device according to one aspect of the present disclosure is a semiconductor device including a plurality of pixels each emitting light, and the semiconductor device includes: a first semiconductor substrate including a transistor of a pixel circuit configured to control light emission of each of the plurality of pixels; a front surface wiring layer provided on a front surface of the first semiconductor substrate; a light emitting element layer provided on a side opposite to the first semiconductor substrate with the front surface wiring layer interposed therebetween; a back surface wiring layer provided on a back surface of the first semiconductor substrate; a second semiconductor substrate including a transistor of a drive circuit configured to drive the pixel circuit; a front surface wiring layer provided on a front surface of the second semiconductor substrate and bonded to the back surface wiring layer of the first semiconductor substrate so as to have electrical contact with the back surface wiring layer of the first semiconductor substrate; and a through-substrate via configured to penetrate the first semiconductor substrate and connect the front surface wiring layer and the back surface wiring layer of the first semiconductor substrate.

A method according to one aspect of the present disclosure is a method for manufacturing a semiconductor device including a plurality of pixels each emitting light, and the method includes: a step of preparing a first semiconductor substrate including a transistor of a pixel circuit configured to control light emission of each of the plurality of pixels and provided with a front surface wiring layer on a front surface thereof; a step of providing a back surface wiring layer on a back surface of the first semiconductor substrate, and providing a through-substrate via penetrating the first semiconductor substrate and connecting the front surface wiring layer and the back surface wiring layer of the first semiconductor substrate; and a step of bonding the back surface wiring layer of the first semiconductor substrate and a front surface wiring layer of a second semiconductor substrate including a transistor of a drive circuit configured to drive the pixel circuit and provided with the front surface wiring layer on a front surface thereof so as to have electrical contact with each other.

### BRIEF DESCRIPTION OF DRAWINGS

FIG. 1 is a diagram illustrating an example of a schematic configuration of a semiconductor device according to an embodiment.

FIG. 2 is a diagram illustrating an example of a pixel circuit.

FIG. 3 is a diagram illustrating an example of a schematic configuration of a semiconductor device.

FIG. 4 is a diagram illustrating an example of a schematic configuration of a semiconductor device.

FIG. 5 is a diagram illustrating an example of a schematic configuration of a semiconductor device.

FIG. 6 is a diagram illustrating an example of a schematic configuration of a semiconductor device.

FIG. 7 is a diagram illustrating an example of a method for manufacturing a semiconductor device.

FIG. 8 is a diagram illustrating an example of a method for manufacturing a semiconductor device.

FIG. 9 is a diagram illustrating an example of a method for manufacturing a semiconductor device.

FIG. 10 is a diagram illustrating an example of a method for manufacturing a semiconductor device.

FIG. 11 is a diagram illustrating an example of a method for manufacturing a semiconductor device.

FIG. 12 is a diagram illustrating an example of a method for manufacturing a semiconductor device.

FIG. 13 is a diagram illustrating a modification of a semiconductor device.

FIG. 14 is a diagram illustrating a modification of a semiconductor device.

FIG. 15 is a diagram illustrating a modification of a semiconductor device.

FIG. 16 is a diagram illustrating a modification of a semiconductor device.

FIG. 17 is a diagram illustrating an example of a wiring pitch.

FIG. 18 is a diagram illustrating a comparative example of a wiring pitch.

FIG. 19 is a diagram illustrating a modification of bonding.

FIG. 20 is a diagram illustrating a modification of bonding.

FIG. 21 is a diagram illustrating a modification of a semiconductor device.

FIG. 22 is a diagram illustrating a modification of a semiconductor device.

FIG. 23 is a diagram illustrating a modification of a semiconductor device.

FIG. 24 is a diagram illustrating a modification of a semiconductor device.

FIG. 25 is a diagram illustrating a modification of a semiconductor device.

FIG. 26 is a diagram illustrating an example of a method for manufacturing a semiconductor device.

FIG. 27 is a diagram illustrating an example of a method for manufacturing a semiconductor device.

FIG. 28 is a diagram illustrating an example of a method for manufacturing a semiconductor device.

FIG. 29 is a diagram illustrating an example of a method for manufacturing a semiconductor device.

FIG. 30 is a diagram illustrating an example of a method for manufacturing a semiconductor device.

FIG. 31 is a diagram illustrating an example of a method for manufacturing a semiconductor device.

FIG. 32 is a diagram illustrating an example of a method for manufacturing a semiconductor device.

FIG. 33 is a diagram illustrating a modification.

FIG. 34 is a diagram illustrating a modification.

FIG. 35 is a diagram illustrating a modification.

FIG. 36 is a diagram illustrating a modification.

FIG. 37 is a diagram illustrating a modification.

FIG. 38 is a diagram illustrating a modification.

FIG. 39 is a diagram illustrating a modification.

FIG. 40 is a diagram illustrating a modification.

FIG. 41 is a diagram illustrating a modification.

FIG. 42 is a diagram illustrating a modification.

FIG. 43 is a diagram illustrating a modification.

FIG. 44 is a diagram illustrating a modification.

FIG. 45 is a diagram illustrating a modification.

FIG. 46 is a diagram illustrating a modification.

FIG. 47 is a diagram illustrating an application example.

FIG. 48 is a diagram illustrating an application example.

FIG. 49 is a diagram illustrating an application example.

FIG. 50 is a diagram illustrating an application example.

FIG. 51 is a diagram illustrating an application example.

FIG. 52 is a diagram illustrating an application example.

FIG. 53 is a diagram illustrating an application example.

FIG. 54 is a diagram illustrating an application example.

### DESCRIPTION OF EMBODIMENTS

Hereinafter, embodiments of the present disclosure will be described in detail with reference to the drawings. Note that, in the following embodiments, the same elements are denoted by the same reference signs, and redundant description will be omitted.

The present disclosure will be described according to the following order of items.
1. Embodiments
2. Modification
3. Example of Effect
4. Other Modifications
5. Application Example

### 1. Embodiments

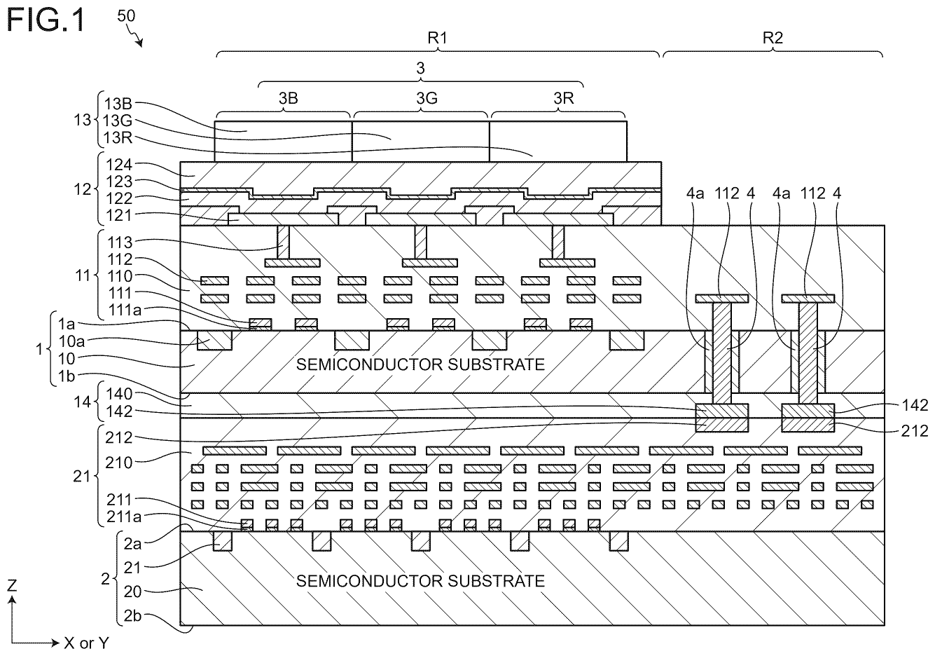

FIG. 1 is a diagram illustrating an example of a schematic configuration of a semiconductor device according to an embodiment. Hereinafter, a semiconductor device 50 will be described as a light emitting device, more specifically, a display device.

The semiconductor device 50 includes a plurality of pixels 3 each emitting light. The plurality of pixels 3 is disposed in an array shape in the XY plane direction. FIG. 1 illustrates three pixels of a pixel 3B, a pixel 3G, and a pixel 3R disposed side by side at an array end portion among the plurality of pixels 3. The pixel 3B emits blue light. The pixel 3G emits green light. The pixel 3R emits red light. The light from the semiconductor device 50 travels along the Z-axis positive direction.

The semiconductor device 50 includes a display region R1 and a non-display region R2. The display region R1 is a region in which the plurality of pixels 3 is provided. The display region R1 can also be referred to as a light emitting region. The non-display region R2 is a region located outside the display region R1 in plan view (when viewed in the Z-axis direction), and is adjacent to the display region R1, for example. The non-display region R2 can also be referred to as a non-light emitting region.

Note that, “to provide” may be understood as meaning of “to form”, “to form a film”, or the like, and may be appropriately replaced as long as there is no contradiction.

The semiconductor device 50 includes two semiconductor substrates. A first semiconductor substrate is referred to as a semiconductor substrate 1 in the drawing. A second semiconductor substrate is referred to as a semiconductor substrate 2 in the drawing. The semiconductor substrate 1 and the semiconductor substrate 2 have a thickness in the Z-axis direction and are provided so as to face each other. The XY plane direction corresponds to a plane direction of the semiconductor substrate 1 and the semiconductor substrate 2.

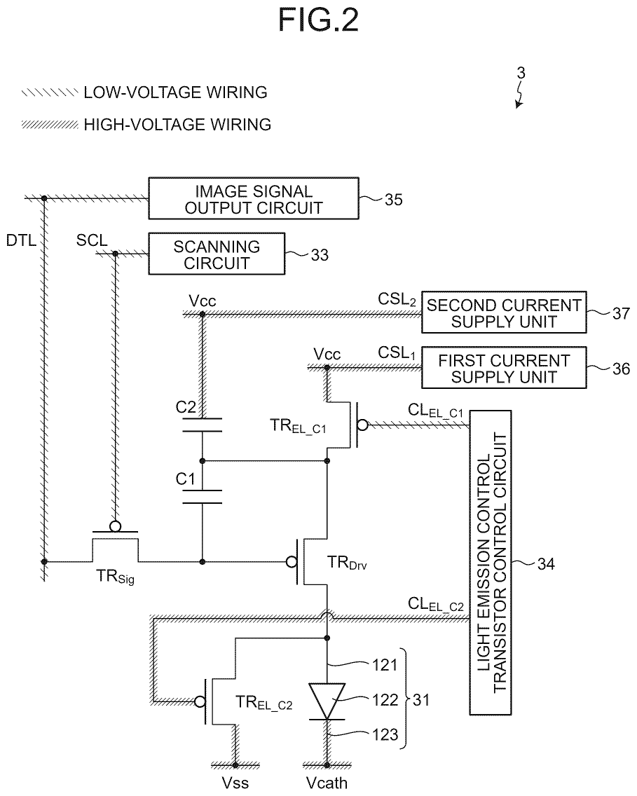

The semiconductor substrate 1 includes a transistor of a pixel circuit that controls light emission of each of the plurality of pixels 3. The semiconductor substrate 1 contains, for example, silicon. A surface of the semiconductor substrate 1 on the Z-axis positive direction side is referred to as a front surface la in the drawing. A surface on the Z-axis negative direction side is referred to as a back surface 1b in the drawing. The main body of the semiconductor substrate 1 is referred to as a main body 10 in the drawing. The main body 10 is provided with a transistor of the pixel circuit and the like. The pixel circuit will be described with reference to FIG. 2.

FIG. 2 is a diagram illustrating an example of the pixel circuit. The light emitting element is referred to as a light emitting element 31 in the drawing. The light emitting element 31 exemplified is an organic light emitting diode (OLED), and includes an anode electrode 121, an organic film 122, and a cathode film 123 to be described later. As the circuit elements, some transistors, capacitance units, and signal lines are illustrated with reference signs.

Specifically, examples of the transistor include a driving transistor TR_{Drv}, an image signal writing transistor TR_{Sig}, a first light emission control transistor TR_{EL_C1}, and a second light emission control transistor TR_{EL_C2}. Examples of the capacitance unit include a first capacitance unit C1 and a second capacitance unit C2. Examples of the signal line include a scanning line SCL, a data line DTL, a first current supply line CSL₁, a second current supply line CSL₂, a first light emission control line CL_{EL_C1}, and a second light emission control line CL_{EL_C2}. Note that, as a matter of course, various types of wiring not denoted by reference signs can also be elements of the pixel circuit.

The driving transistor TR_{Drv} is a control transistor that controls a current flowing through the light emitting element 31. The driving transistor TR_{Drv} has one source/drain region connected to the anode electrode 121 of the light emitting element 31, the other source/drain region connected to one source/drain region of the first light emission control transistor TR_{EL_C1}, and a gate connected to one source/drain region of the image signal writing transistor TR_{EL_C1} and one electrode of the first capacitance unit C1.

The image signal writing transistor TR_{Sig} is a row selection transistor that switches a signal voltage. The image signal writing transistor TR_{Sig} has the other source/drain region connected to an image signal output circuit 35 via the data line DTL and a gate connected to a scanning circuit 33 via the scanning line SCL.

The first light emission control transistor TR_{EL_C1} is a column selection transistor that switches a power supply voltage. The first light emission control transistor TR_{EL_C1} has the other source-drain region connected to a first current supply unit 36 via the first current supply line CSL₁ and a gate connected to a light emission control transistor control circuit 34 via the first light emission control line CL_{EL_C1}. A drive voltage Vcc is applied from the first current supply unit 36 to the other source/drain region of the first light emission control transistor TR_{EL_C1}.

The second light emission control transistor TR_{EL_C2} is a transistor that resets voltage (anode voltage) applied to the light emitting element 31. The second light emission control transistor TR_{EL_C2} has one source/drain region connected to the anode electrode 121 of the light emitting element 31, the other source/drain region connected to the reset voltage line Vss, and a gate connected to the light emission control transistor control circuit 34 via the second light emission control line CL_{EL_C2}.

The first capacitance unit C1 and the second capacitance unit C2 are connected in series to each other. One electrode of the first capacitance unit C1 is connected to the gate of the driving transistor TR_{Drv} and the source/drain region of the image signal writing transistor TR_{Sig}. The other electrode of the first capacitance unit C1 and one electrode of the second capacitance unit C2 are connected to the other source/drain region of the driving transistor TR_{Drv} and one source/drain region of the first light emission control transistor TR_{EL_C1}. The other electrode of the second capacitance unit C2 is connected to a second current supply unit 37 via the second current supply line CSL2. The drive voltage Vcc is applied from the second current supply unit 37 to the other electrode of the second capacitance unit C2.

The anode electrode 121 of the light emitting element 31 is connected to one source/drain region of the driving transistor TR_{Drv} and one source/drain region of the reset transistor TRE_{L_C2}. The cathode film 123 is connected to a power supply line Vcath.

The driving transistor TR_{Drv}, the image signal writing transistor TR_{Sig}, the first light emission control transistor TRE_{L_C1}, and the second light emission control transistor TR_{EL_C2} described above are all p-type channel MOSFETS, for example, and are provided in an n-type well provided in a p-type silicon semiconductor substrate.

The detailed operation of the pixel circuit having the above configuration is described in, for example, Patent Literature 2, and thus the description thereof is omitted here. Note that, the circuit configuration illustrated in FIG. 2 is merely an example, and various other known circuit configurations may be adopted.

One of the points to be noted is that, as indicated by hatching in FIG. 2, low-voltage wiring to which relatively low voltage is supplied and high-voltage wiring to which relatively high voltage is supplied can be mixed. For example, voltage of about 3 V is supplied to the low-voltage wiring. For example, voltage of about 10 V is supplied to the high-voltage wiring.

Returning to FIG. 1, for example, a transistor constituting the pixel circuit as described above is provided in the main body 10 of the semiconductor substrate 1. In addition, in this example, the main body 10 of the semiconductor substrate 1 is also provided with a separation region 10a. The separation region 10a is provided at a corresponding position between the adjacent pixels 3 and electrically separates the pixels 3 from each other.

As a layer provided on the semiconductor substrate 1, a front surface wiring layer 11, a light emitting element layer 12, a filter layer 13, and a back surface wiring layer 14 are illustrated in FIG. 1. The back surface wiring layer 14, the semiconductor substrate 1, the front surface wiring layer 11, the light emitting element layer 12, and the filter layer 13 are located in this order in the Z-axis positive direction.

The front surface wiring layer 11 is provided on the front surface 1a of the semiconductor substrate 1. In this example, the front surface wiring layer 11 is a multilayer wiring layer. The main body of the front surface wiring layer 11 is referred to as a main body 110 in the drawing. The main body 110 is, for example, an insulator. The front surface wiring layer 11 is provided with some elements of the pixel circuit, and a gate electrode 111, wiring 112, and a via 113 from among these elements are illustrated with reference signs.

The gate electrode 111 is a gate electrode of a field effect transistor (FET), and is disposed with respect to a drain-source region thereof via an insulating film 111a. The wiring 112 includes wiring of the pixel circuit. An example of the material of the wiring 112 is copper (Cu) or the like. Various types of wiring 112 are provided over each wiring layer of the front surface wiring layer 11. The exemplified via 113 is a via that connects the wiring 112 and the anode electrode 121 to be described later.

The light emitting element layer 12 is provided on the side opposite to the semiconductor substrate 1 with the front surface wiring layer 11 interposed therebetween. In this example, the light emitting element included in the light emitting element layer 12 is the OLED. Specifically, the light emitting element layer 12 includes the anode electrode 121, the organic film 122, the cathode film 123, and a protective film 124. The anode electrode 121, the organic film 122, the cathode film 123, and the protective film 124 are disposed in this order in the Z-axis positive direction. Note that, “film” and “layer” may be appropriately replaced as long as there is no contradiction.

The anode electrode 121, the organic film 122, and the cathode film 123 are included in the OLED. The anode electrode 121 is provided for each pixel 3. The organic film 122 and the cathode film 123 are provided in common over the plurality of pixels 3. The organic film 122 is configured to emit light including blue light, green light, and red light, more specifically, white light. For example, the organic film 122 may have a structure in which an organic film that emits blue light, an organic film that emits green light, and an organic film that emits red light are stacked. The protective film 124 protects the organic film 122 from, for example, moisture.

The filter layer 13 is provided on the side opposite to the front surface wiring layer 11 with the light emitting element layer 12 interposed therebetween. The filter layer 13 allows light of the color of the corresponding pixel 3 among the white light from the light emitting element layer 12 to pass therethrough. Specifically, the filter layer 13 includes a filter 13B that allows blue light to pass in the pixel 3B, a filter 13G that allows green light to pass in the pixel 3G, and a filter 13R that allows red light to pass in the pixel 3R.

Although not illustrated, a lens layer including a lens (for example, a microlens) for improving the light extraction efficiency from the light emitting element layer 12 may be provided on the filter layer 13.

The back surface wiring layer 14 is provided on the back surface 1b of the semiconductor substrate 1. In this example, the back surface wiring layer 14 is a single-layer wiring layer. The main body of the back surface wiring layer 14 is referred to as a main body 140 in the drawing. The main body 140 is, for example, an insulator. As an element provided in the back surface wiring layer 14, wiring 142 is illustrated with a reference sign. An example of the material of the wiring 142 is Cu or the like. The back surface wiring layer 14 includes the wiring 142 whose lower surface (surface on the Z-axis negative direction side) is exposed to the lower surface of the back surface wiring layer 14. The exposed wiring 142 can also be referred to as an electrode.

The semiconductor substrate 2 includes a transistor of a drive circuit that drives the pixel circuit. The semiconductor substrate 1 contains, for example, silicon. A surface of the semiconductor substrate 2 on the Z-axis positive direction side is referred to as a front surface 2a in the drawing. A surface on the Z-axis negative direction side is referred to as a back surface 2b in the drawing. The front surface 2a of the semiconductor substrate 2 faces the back surface 1b of the semiconductor substrate 1.

As a layer provided on the semiconductor substrate 2, a front surface wiring layer 21 is illustrated in FIG. 1. The semiconductor substrate 2 and the front surface wiring layer 21 are located in this order in the Z-axis positive direction.

The front surface wiring layer 21 is provided on the front surface 2a of the semiconductor substrate 2. The main body of the front surface wiring layer 21 is referred to as a main body 210 in the drawing. The main body 210 is, for example, an insulator. As elements of the drive circuit provided in the front surface wiring layer 21, the gate electrode 211 and wiring 212 are illustrated with reference signs.

The gate electrode 211 is a gate electrode of a field effect transistor, and is provided with respect to a drain-source region thereof via an insulating film 211a. The wiring 212 includes wiring of the drive circuit. An example of the material of the wiring 212 is Cu or the like. Various types of wiring 212 are provided in the back surface wiring layer 14. Although not illustrated in the drawing, a via or the like may also be provided. The front surface wiring layer 21 includes the wiring 212 whose upper surface (surface on the Z-axis positive direction side) is exposed to the upper surface of the front surface wiring layer 21. The exposed wiring 212 can also be referred to as an electrode.

The front surface wiring layer 21 of the semiconductor substrate 2 is bonded to the back surface wiring layer 14 so as to have electrical contact with the back surface wiring layer 14 of the semiconductor substrate 1. Specifically, the wiring 142 exposed to the lower surface of the back surface wiring layer 14 of the semiconductor substrate 1 described above and the wiring 212 exposed to the upper surface of the front surface wiring layer 21 of the semiconductor substrate 2 are joined and electrically connected. This joining is also referred to as electrode joining. The wiring 142 and wiring 212 that are joined to each other are also referred to as joined wiring. The joined wiring provides electrical connection between the back surface wiring layer 14 of the semiconductor substrate 1 and the front surface wiring layer 21 of the semiconductor substrate 2.

In addition, in the present embodiment, the semiconductor device 50 includes a through-substrate via 4. The through-substrate via 4 penetrates the semiconductor substrate 1 and connects the front surface wiring layer 11 and the back surface wiring layer 14 of the semiconductor substrate 1. By such a through-substrate via 4 and the above-described electrode joining, electrical connection is obtained over the front surface wiring layer 21 of the semiconductor substrate 2, the back surface wiring layer 14, and the front surface wiring layer 11 of the semiconductor substrate 1. Note that, in the example illustrated in FIG. 1, the through-substrate via 4 is electrically separated from the semiconductor substrate 1 by an insulating film 4a.

The through-substrate via 4 is provided in at least the non-display region R2 of the display region R1 and the non-display region R2. In the example illustrated in FIG. 1, the through-substrate via 4 is provided in the non-display region R2. The through-substrate via 4 is not provided in the display region R1, and accordingly, a wiring region in the display region R1 can be easily secured. Note that, the number of the through-substrate vias 4 is not limited to the example illustrated in FIG. 1.

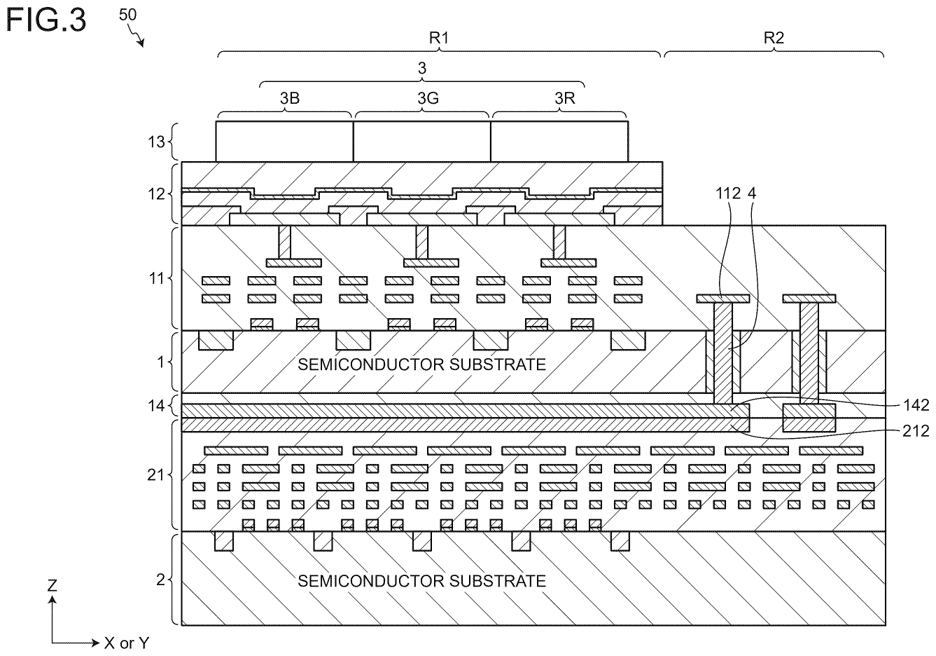

According to the semiconductor device 50 having the above configuration, not only the front surface wiring layer 11 is provided on the front surface 1a of the semiconductor substrate 1, but also the back surface wiring layer 14 is provided on the back surface 1b of the semiconductor substrate 1. Accordingly, more wiring regions can be secured. For example, high performance such as high definition, high speed, and high image quality can be achieved. Some specific examples will be described with reference to FIGS. 3 to 6.

FIGS. 3 to 6 are diagrams illustrating an example of a schematic configuration of a semiconductor device. In the example illustrated in FIG. 3, the back surface wiring layer 14 of the semiconductor substrate 2 includes the wiring 142 not only in the non-display region R2 in which the through-substrate via 4 is provided but also in the display region R1. The elements of the pixel circuit may be provided over the front surface wiring layer 11 and the back surface wiring layer 14. Since more wiring regions can be utilized than in the case of using only the front surface wiring layer 11, for example, wiring resistance can be reduced or an area for forming a capacitive element can be secured.

In addition, as illustrated in the drawing, the joined wiring (wiring 142 and wiring 212 that are joined to each other) extends in the same direction. By using a joined wiring having a large cross-sectional area, an effect such as the reduction of wiring resistance can be further enhanced. The reliability of wiring is also improved.

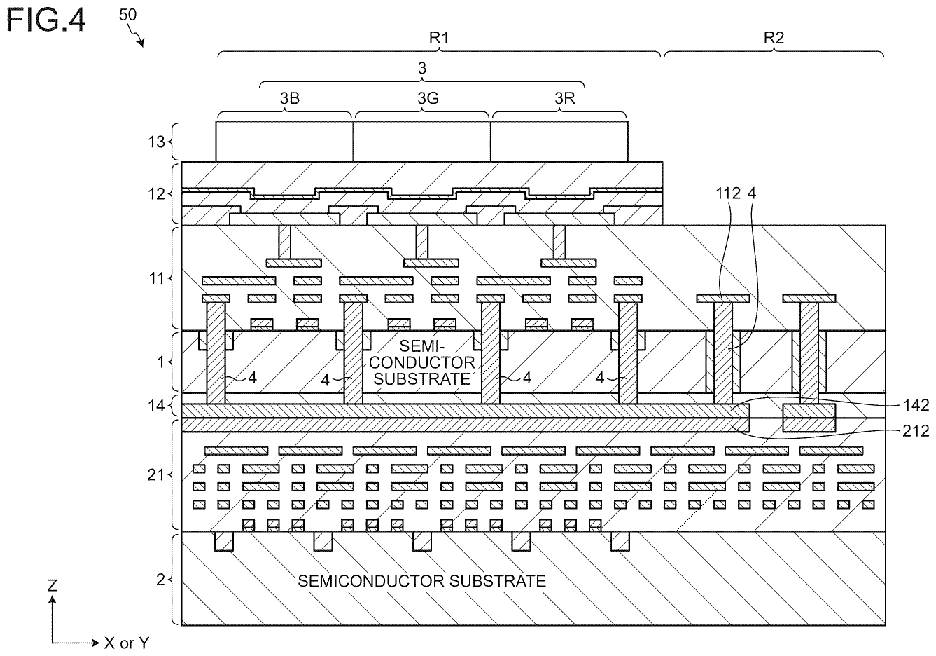

In the example illustrated in FIG. 4, the through-substrate via 4 is provided in both the display region R1 and the non-display region R2. By providing the through-substrate via 4 also in the display region R1, the possibility is increased that the front surface wiring layer 11 and the back surface wiring layer 14 can be connected more efficiently. In this example, the through-substrate via 4 is provided for each pixel 3 in the display region R1. These through-substrate vias 4 may be vias for low-voltage wiring (FIG. 2). A leakage current or the like from the through-substrate via 4 to the semiconductor substrate 1, which may occur in the case of high-voltage wiring, is likely to avoid the problem. IR drop due to wiring is also reduced. Note that, a configuration may be adopted in which one through-substrate via 4 is provided for the plurality of pixels 3.

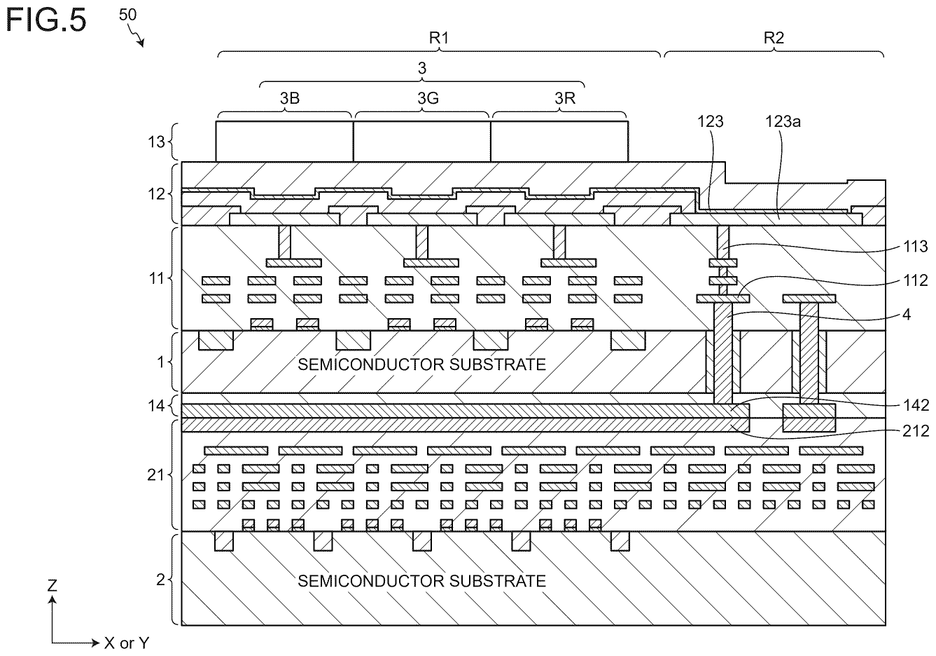

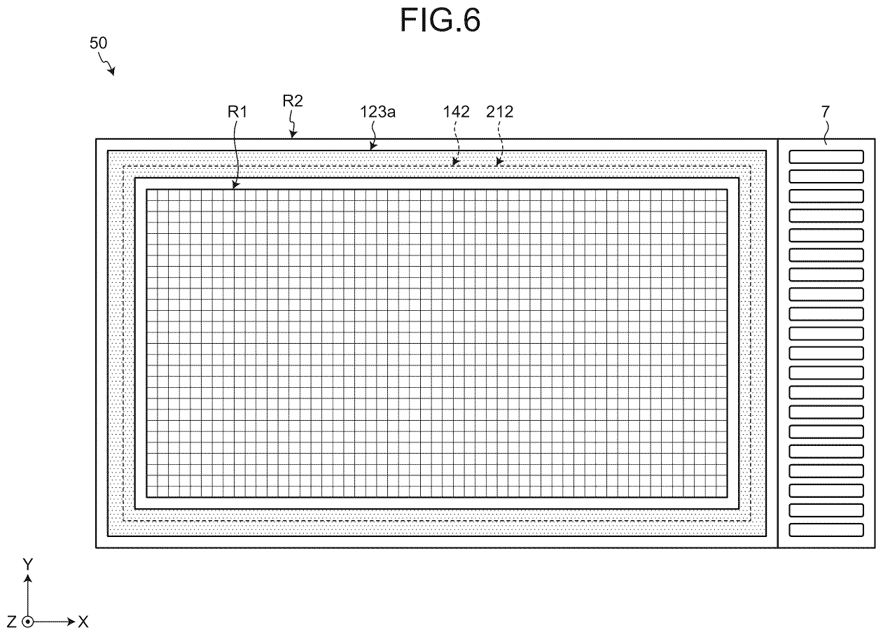

In the example illustrated in FIG. 5, the back surface wiring layer 14 of the semiconductor substrate 1 includes the wiring 142 connected to the cathode film 123 so as to have the same potential as the cathode film 123 of the light emitting element layer 12. Specifically, in the non-display region R2, a cathode electrode 123a is provided on the front surface wiring layer 11 of the semiconductor substrate 1. The cathode electrode 123a provides a cathode contact region for cathode potential control. The cathode film 123 of the light emitting element layer 12 extends from the display region R1 to the non-display region R2 and is connected to the cathode electrode 123a. The cathode electrode 123a is connected to the wiring 142 of the back surface wiring layer 14 via the via 113 and the wiring 112 of the front surface wiring layer 11 and the through-substrate via 4. This will be further described with reference to FIG. 6.

FIG. 6 illustrates a schematic configuration of the semiconductor device 50 in plan view. Some elements located behind other elements are illustrated in dashed lines. The cathode electrode 123a described above extends along the outer periphery of the display region R1 so as to surround the display region R1. The semiconductor device 50 includes a pad portion 7 connected to one side of the non-display region R2 and used for power supply or the like. The pad portion 7 includes, for example, a cathode power supply terminal and the like.

The wiring 142 connected to the cathode electrode 123a may have a planar shape spreading over the entire display region R1. The electrical connection of the entire cathode electrode 123a is strengthened. For example, the influence (shading or the like) of a voltage drop appearing in each portion of the cathode electrode 123a due to the difference in the distance from the pad portion 7 can be reduced, and the luminance of each portion (each pixel 3) of the display region R1 can be made uniform. In addition, in this example, the wiring 212 joined to the wiring 142 also has a planar shape spreading over the entire display region R1. The electrical connection of the entire cathode electrode 123a is strengthened.

When the width (length in the XY plane direction) of the cathode electrode 123a is increased in order to reduce the influence of the voltage drop, it is difficult to miniaturize a device such as frame narrowing. By utilizing the wiring 142 (and the wiring 212) of the back surface wiring layer 14 of the semiconductor substrate 1 as described above, it is possible to achieve both frame narrowing and luminance uniformity. In particular, by utilizing the wiring 142 of the display region R1, the layout efficiency can be enhanced and the device can be miniaturized.

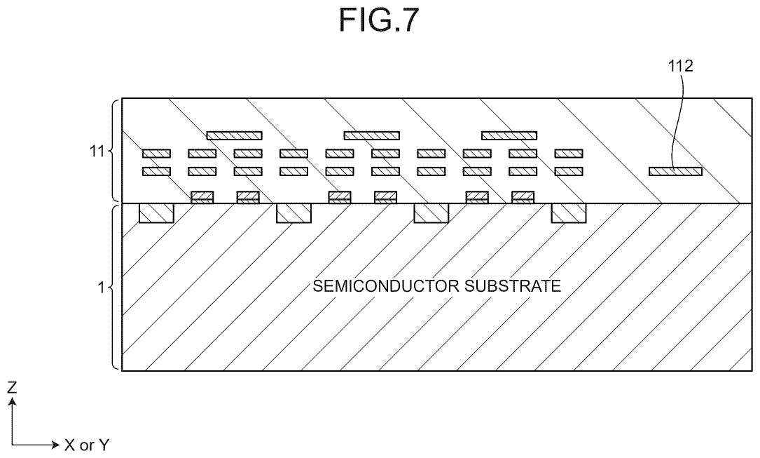

An example of a method for manufacturing the semiconductor device 50 having the above-described configuration will be described with reference to FIGS. 7 to 12.

FIGS. 7 to 12 are diagrams illustrating an example of a method for manufacturing a semiconductor device. In this example, the semiconductor substrate 1 and the semiconductor substrate 2 are both in a wafer state, and the back surface wiring layer 14 of the semiconductor substrate 1 and the front surface wiring layer 21 of the semiconductor substrate 2 are bonded together. Description of contents overlapping with the above description will be omitted as appropriate.

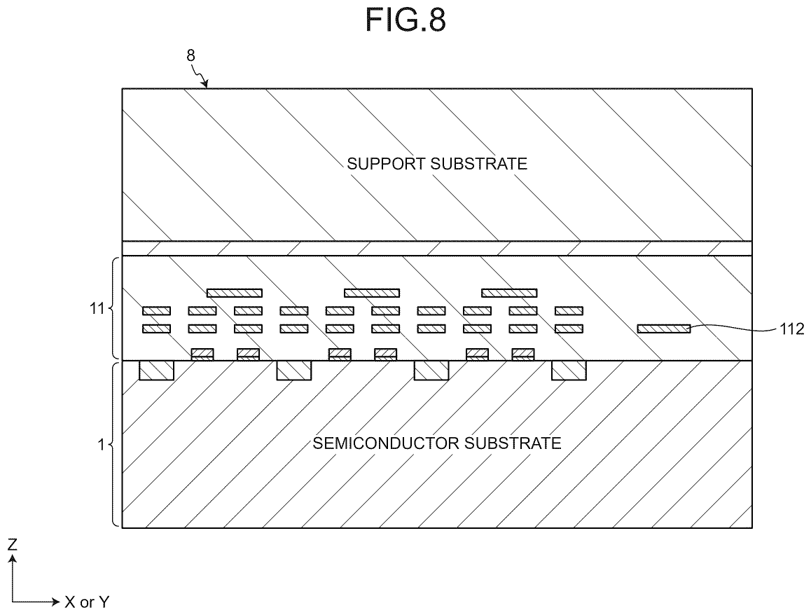

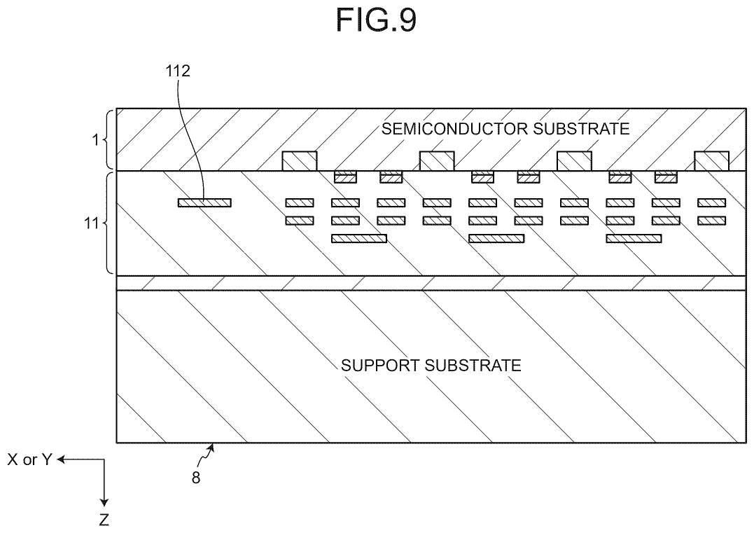

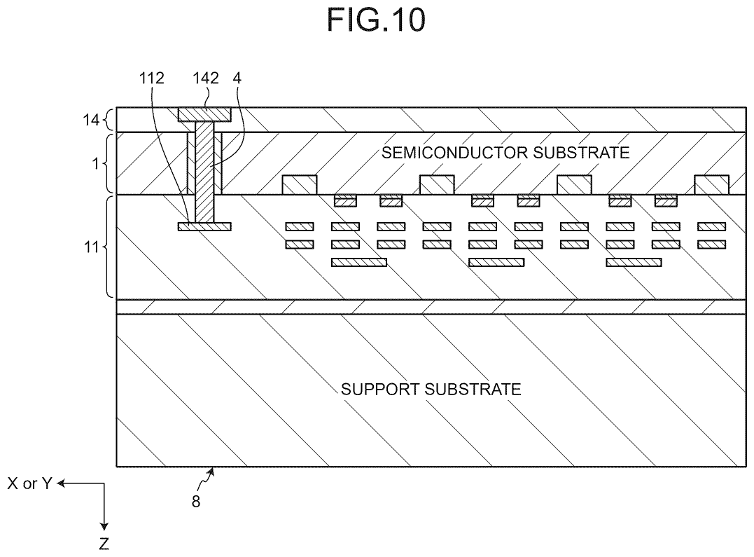

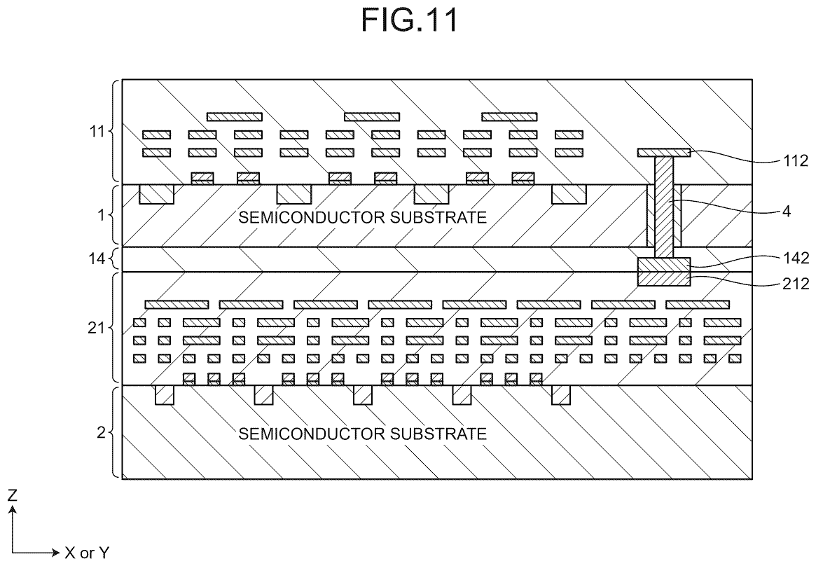

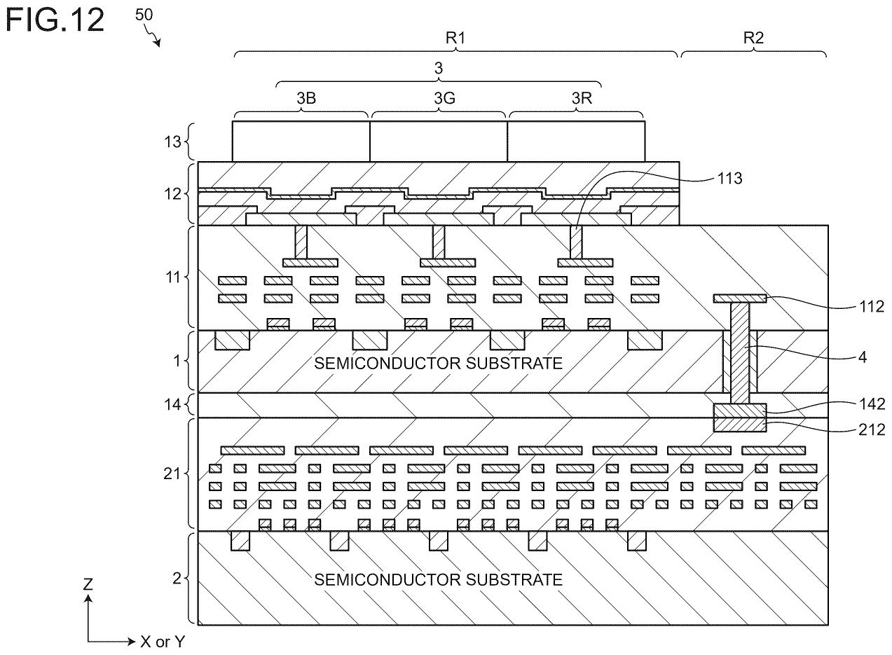

As illustrated in FIG. 7, the semiconductor substrate 1 provided with the front surface wiring layer 11 including the wiring 112 and the like is prepared. As illustrated in FIG. 8, the upper surface (the surface on the Z-axis positive direction side) of the front surface wiring layer 11 is bonded to a support substrate 8 provided with an oxide film or the like. As illustrated in FIG. 9, the film of the semiconductor substrate 1 is thinned. As illustrated in FIG. 10, the back surface wiring layer 14 is provided on the semiconductor substrate 1, and the through-substrate via 4, the wiring 142, and the like are provided on the semiconductor substrate 1. Although not illustrated in the drawing, the semiconductor substrate 2 provided with the front surface wiring layer 21 is manufactured and prepared by, for example, a process different from that of the semiconductor substrate 1. As illustrated in FIG. 11, the back surface wiring layer 14 of the semiconductor substrate 1 and the front surface wiring layer 21 of the semiconductor substrate 2 are bonded to each other so as to have electrical contact with each other. The wiring 142 of the corresponding back surface wiring layer 14 and the wiring 212 of the front surface wiring layer 21 are joined and electrically connected. The support substrate 8 is removed. As illustrated in FIG. 12, the via 113 connected to the anode electrode 121 is provided in the front surface wiring layer 11 of the semiconductor substrate 1, and the light emitting element layer 12 and the filter layer 13 are sequentially provided thereon. Note that, the lens layer described above may be further provided.

For example, the semiconductor device 50 can be manufactured as described above.

### 2. Modification

The disclosed technology is not limited to the above embodiment. Some modifications will be described.

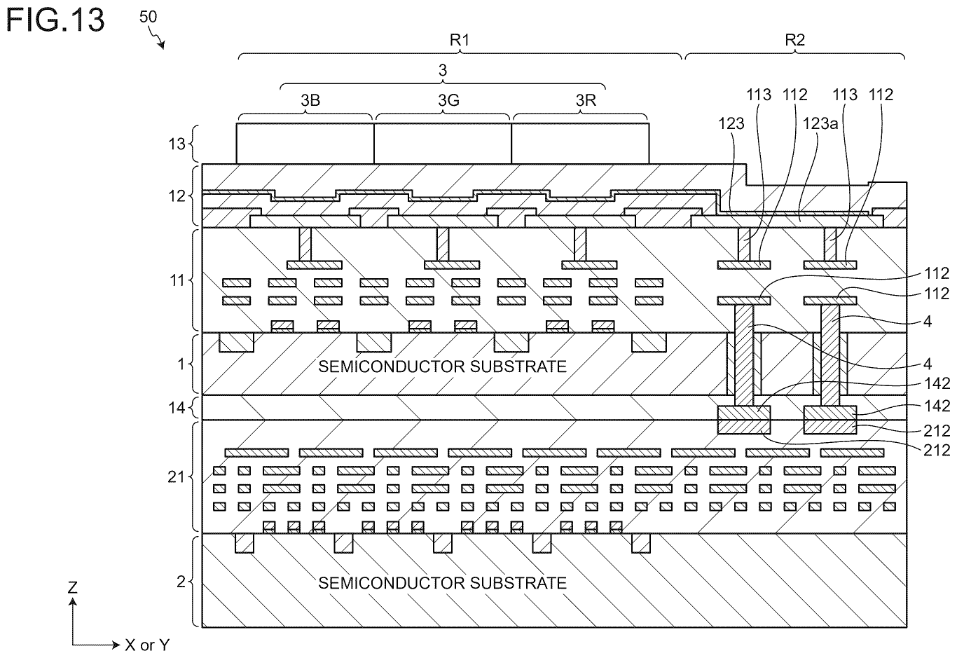

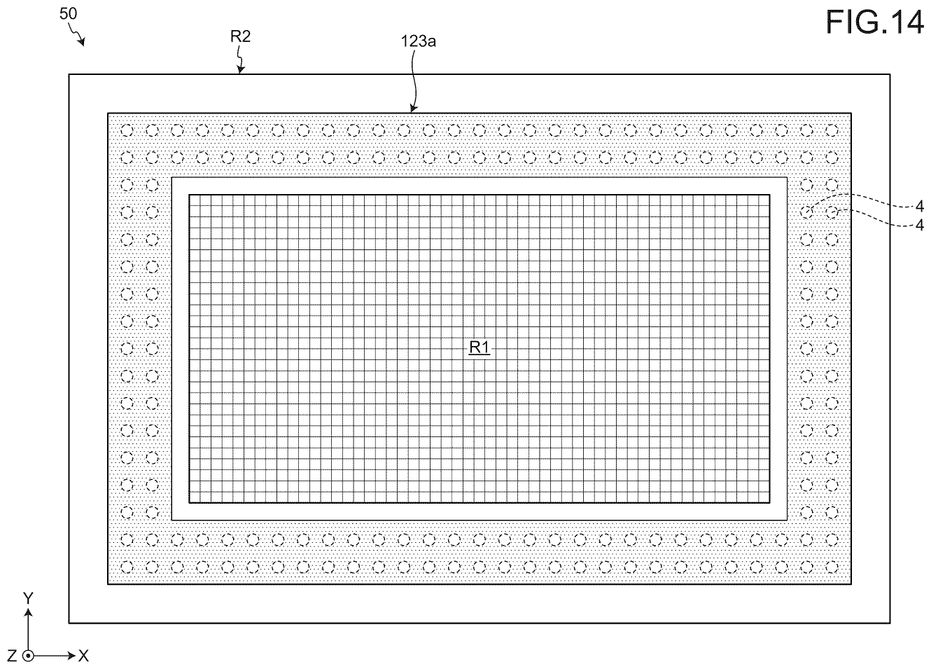

As illustrated in the drawings described above, in one embodiment, the through-substrate via 4 may overlap the cathode electrode 123a in plan view (when viewed in the Z-axis direction). This will be described again with reference to FIGS. 13 and 14.

FIGS. 13 and 14 are diagrams illustrating a modification of a semiconductor device. As described above, the cathode electrode 123a (cathode contact region) is provided outside the display region R1. The through-substrate via 4 overlaps the cathode electrode 123a in plan view (as viewed in the Z-axis direction). By disposing the through-substrate via 4 in such a region, the non-display region R2 including the through-substrate via 4 can be made as narrow as possible, and the semiconductor device 50 can be further miniaturized.

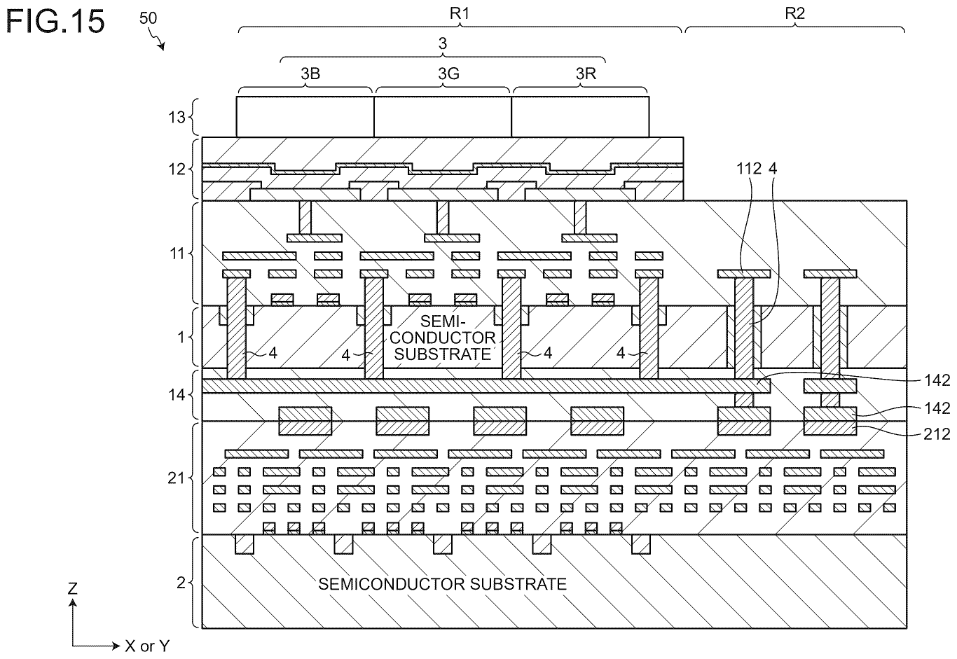

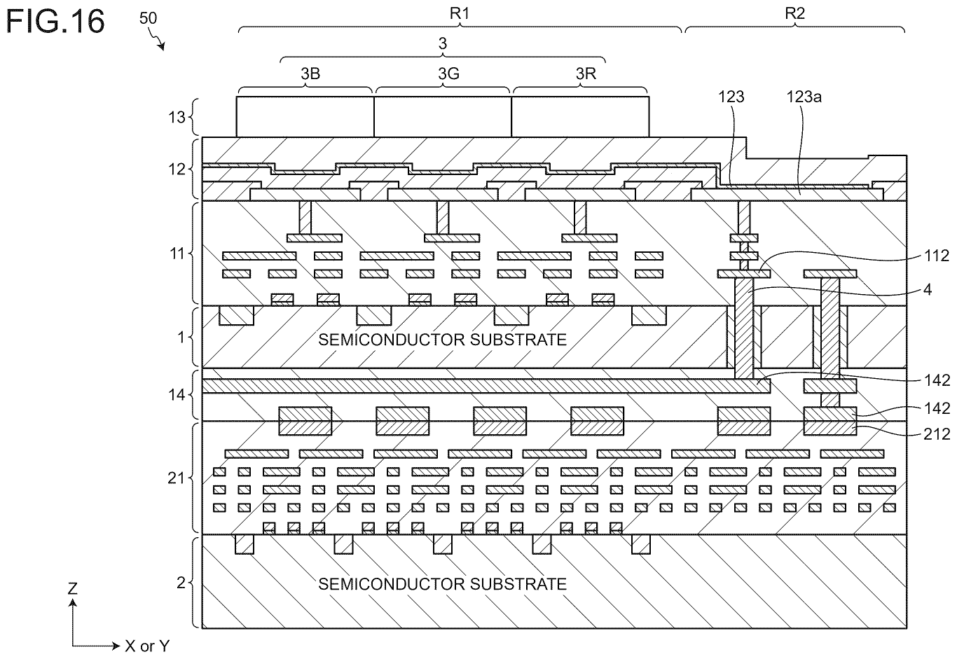

In one embodiment, the back surface wiring layer 14 of the semiconductor substrate 1 may be a multilayer wiring layer. This will be described with reference to FIGS. 15 and 16.

FIGS. 15 and 16 are diagrams illustrating a modification of a semiconductor device. The back surface wiring layer 14 of the semiconductor substrate 1 is the multilayer wiring layer. The wiring 142 of the lowermost (Z-axis negative direction side) wiring layer has a wiring pattern (for example, a uniform wiring pattern) suitable for joining to the wiring 212 of the front surface wiring layer 21 of the semiconductor substrate 2. As a result, it is easy to secure a process margin required for joining the wiring 142 and the wiring 212. There is an advantage that the joining process is made robust or the like. The wiring 142 of another wiring layer may have an arbitrary wiring pattern, and layout freedom can be improved accordingly.

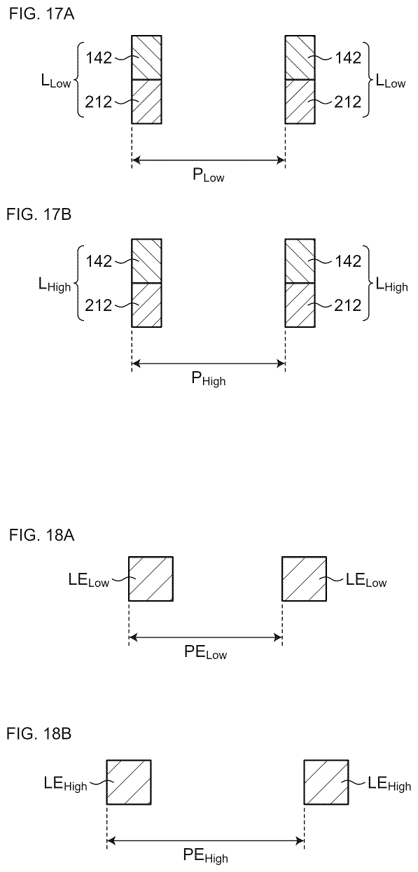

In one embodiment, the joined wiring may include the low-voltage wiring and the high-voltage wiring disposed at the same wiring pitch. This is because the degree of freedom in design is improved because the effective wiring thickness of the joined wiring is large, so that the joined wiring width can be suppressed or the like. This will be described with reference to FIGS. 17 and 18.

FIG. 17 is a diagram illustrating an example of the wiring pitch. The joined wiring that is the low-voltage wiring is referred to as low-voltage wiring L_{Low} in the drawing. The joined wiring that is the high-voltage wiring is referred to as high-voltage wiring L_{High} in the drawing. In (A) of FIG. 17, the low-voltage wiring L_{Low} and a wiring pitch P_{Low} thereof are illustrated. The wiring width of the low-voltage wiring L_{Low} is designed so that EM does not occur. The wiring pitch P_{Low} is designed to maintain insulation resistance. In (B) of FIG. 17, the high-voltage wiring L_{High} and a wiring pitch P_{High} thereof are illustrated. The wiring width of the high-voltage wiring L_{High} is designed so that EM does not occur. The wiring pitch P_{High} is designed to maintain insulation resistance.

As understood from FIG. 17, the wiring width of the high-voltage wiring L_{High} can be designed to be the same as the wiring width of the low-voltage wiring L_{Low}, and the wiring pitch P_{High} of the high-voltage wiring L_{High} can be designed to be the same as the wiring pitch P_{Low} of the low-voltage wiring L_{Low}. As a result, it is possible to obtain advantages such as making the areas of the circuit using the high-voltage wiring and the circuit using the low-voltage wiring equal in plan view and facilitating the design.

FIG. 18 is a diagram illustrating a comparative example of the wiring pitch. The low-voltage wiring of the comparative example is referred to as low-voltage wiring LE_{Low} in the drawing. The high-voltage wiring of the comparative example is referred to as high-voltage wiring LE_{High} in the drawing. Each of the low-voltage wiring LE_{Low} and the high-voltage wiring LE_{High}is single-layer wiring. In (A) of FIG. 18, the low-voltage wiring LE_{Low} and a wiring pitch PE_{Low} thereof are illustrated. The wiring width of the low-voltage wiring LE_{Low} is designed so that EM does not occur. The wiring pitch PE_{Low} is designed to maintain insulation resistance. In (B) of FIG. 18, the high-voltage wiring LE_{High} and a wiring pitch PE_{High} thereof are illustrated. The wiring width of the high-voltage wiring LE_{High} is designed so that EM does not occur. The wiring pitch PE_{High} is designed to maintain insulation resistance.

As can be understood from FIG. 18, the wiring pitch PE_{High} of the high-voltage wiring LE_{High} can be larger than the wiring pitch PE_{Low} of the low-voltage wiring LE_{Low}. A sufficient wiring thickness that is single-layer wiring and does not cause EM cannot be obtained, and the wiring width increases. As a result, there are disadvantages that the area of the circuit using the high-voltage wiring is larger than that of the circuit using the low-voltage wiring, it is difficult to obtain the degree of freedom in design, and the like.

In one embodiment, at least one of the semiconductor substrate 1 and the semiconductor substrate 2 may be a silicon semiconductor substrate containing silicon. For example, by using a silicon substrate for the semiconductor substrate 2 for a drive circuit, the possibility is increased that the most advanced semiconductor process can be applied to transistor formation and the like, and high integration, high speed, and low power consumption are easily realized. By forming a transistor on the semiconductor substrate 1 for a pixel circuit by using a silicon substrate for the semiconductor substrate 1 for the pixel circuit, advantages such as high reliability and low variation are easily obtained as compared with the case of using a TFT transistor such as a polysilicon film (Poly-Si) or IGZO, for example, and thus the possibility of improving image quality is increased.

In one embodiment, the transistor provided on the semiconductor substrate 1 and the transistor provided on the semiconductor substrate 2 may operate at different power supply voltages. For example, the transistor provided on the semiconductor substrate 1 may be a high breakdown voltage transistor that operates at a relatively high power supply voltage, and the transistor provided on the semiconductor substrate 2 may be a low breakdown voltage transistor that operates at a relatively low power supply voltage. A process of manufacturing only a high breakdown voltage transistor may be used for manufacturing the semiconductor substrate 1, and a process of manufacturing only a low breakdown voltage transistor may be used for manufacturing the semiconductor substrate 2. In the manufacturing process, for example, methods for forming an insulating film of a gate can be different. The manufacturing process can be simplified (for example, the number of processes can be reduced) as compared with the case where transistors of different manufacturing processes are mixed in the same semiconductor substrate. Note that, in a case where a high breakdown voltage transistor (for example, a transistor near the pixel circuit) is required for a transistor in the drive circuit, the transistor may be provided not on the semiconductor substrate 2 but on the semiconductor substrate 1.

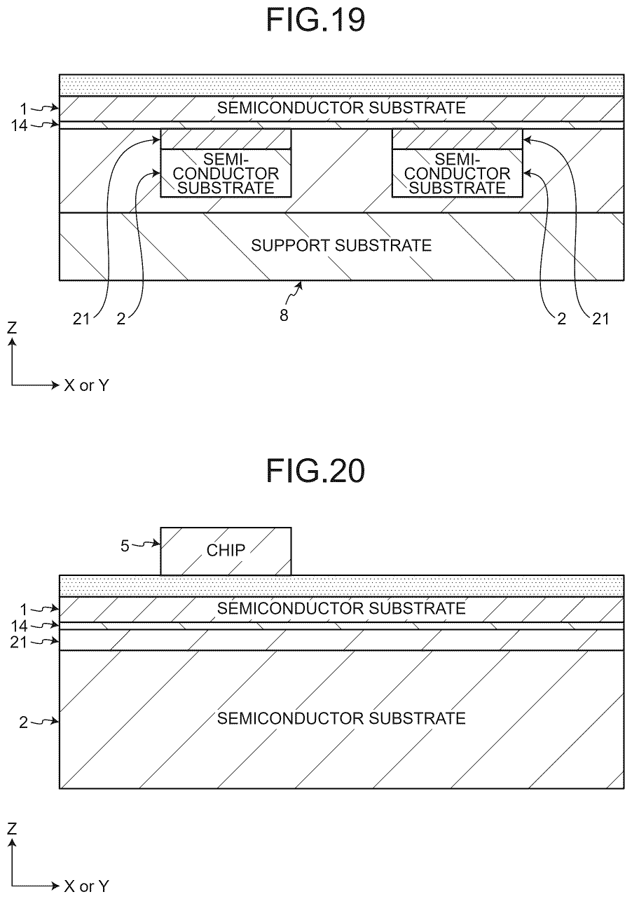

In one embodiment, the back surface wiring layer 14 of the semiconductor substrate 1 and the front surface wiring layer 21 of the semiconductor substrate 2 may be bonded together in a state where one of the semiconductor substrate 1 and the semiconductor substrate 2 is in a wafer state and the other is in a chip state. Even when the sizes (chip sizes) of the semiconductor substrate 1 and the semiconductor substrate 2 are different from each other, it is possible to increase the yield of the smaller substrate. For example, the manufacturing cost can be reduced. This will be described with reference to FIGS. 19 and 20.

FIGS. 19 and 20 are diagrams illustrating a modification of bonding. In this example, the semiconductor substrate 1 is in a wafer state, and the semiconductor substrate 2 is in a chip state. This is useful when the size of the semiconductor substrate 2 is smaller than the size of the semiconductor substrate 1. In addition, multi-functionalization can be achieved by joining chips (for example, a memory, a CMOMS sensor, or the like) with different manufacturing processes. In the example illustrated in FIG. 20, a chip 5 different from the semiconductor substrate 1 and the semiconductor substrate 2 is provided (for example, bonded) on the side opposite to the semiconductor substrate 2 with the semiconductor substrate 1 interposed therebetween.

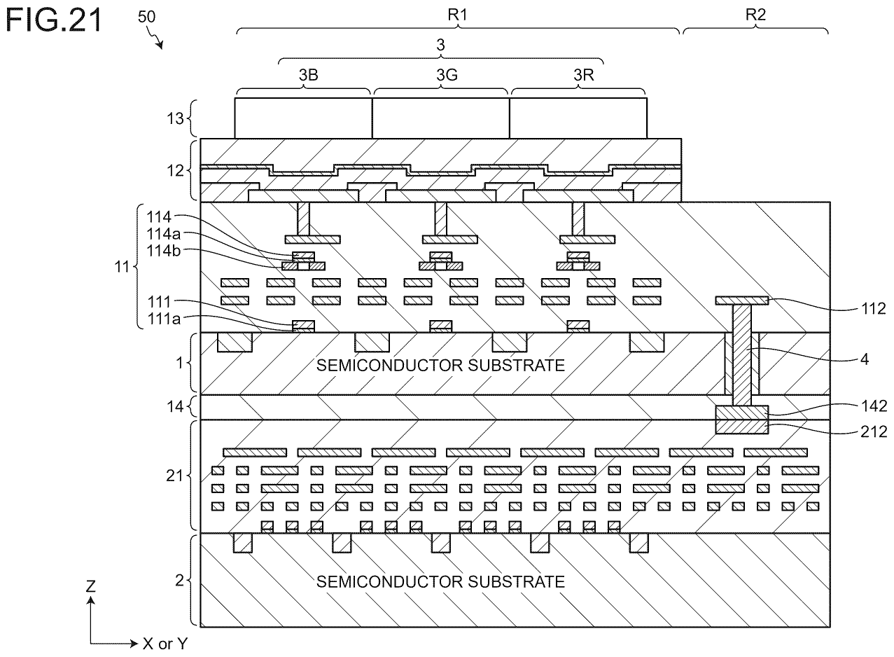

In one embodiment, the front surface wiring layer 11 of the semiconductor substrate 1 may also include a transistor of the pixel circuit. This will be described with reference to FIG. 21.

FIG. 21 is a diagram illustrating a modification of a semiconductor device. The transistor of the pixel circuit is provided not only in the main body 10 of the semiconductor substrate 1 but also in the front surface wiring layer 11 of the semiconductor substrate 1. For example, the degree of freedom of the pixel circuit layout can be improved. In FIG. 21, a gate electrode 114, an insulating film 114a, and a source/drain 114b of the transistor provided in the front surface wiring layer 11 are denoted by reference signs. Various known materials, transistor structures, and the like may be used. Examples of the channel material include an oxide semiconductor (IGZO or the like), single crystal silicon, and the like. Examples of the transistor structure include a planar transistor, a fin field-effect transistor (Fin-FET), and the like.

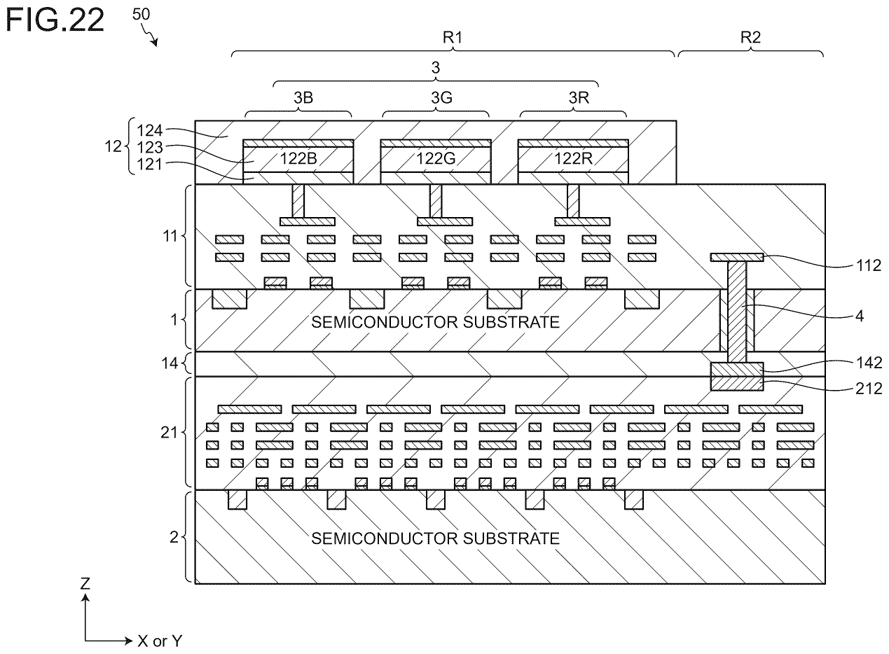

In one embodiment, the light emitting element layer 12 is provided for each pixel 3, and each pixel may include an organic film that emits blue, green, or red light. This will be described with reference to FIG. 22.

FIG. 22 is a diagram illustrating a modification of a semiconductor device. The light emitting element layer 12 includes an organic film 122B that emits blue light in the pixel 3B, an organic film 122G that emits green light in the pixel 3G, and an organic film 122R that emits red light in the pixel 3R. Each of the organic film 122B, the organic film 122G, and the organic film 122R may have a single layer structure. It is possible to operate at lower voltage than in the case of using a stacked structure. The number of options for the process of the semiconductor substrate 1 can be increased by the low-voltage design. There is also an advantage that the filter layer 13 can be unnecessary.

In the above embodiment, the case where the light emitting element is the OLED has been described as an example. However, the light emitting element is not limited to the OLED. Any light emitting element capable of emitting light including visible light may be used. Examples of other light emitting elements include liquid crystals, LEDs, and the like.

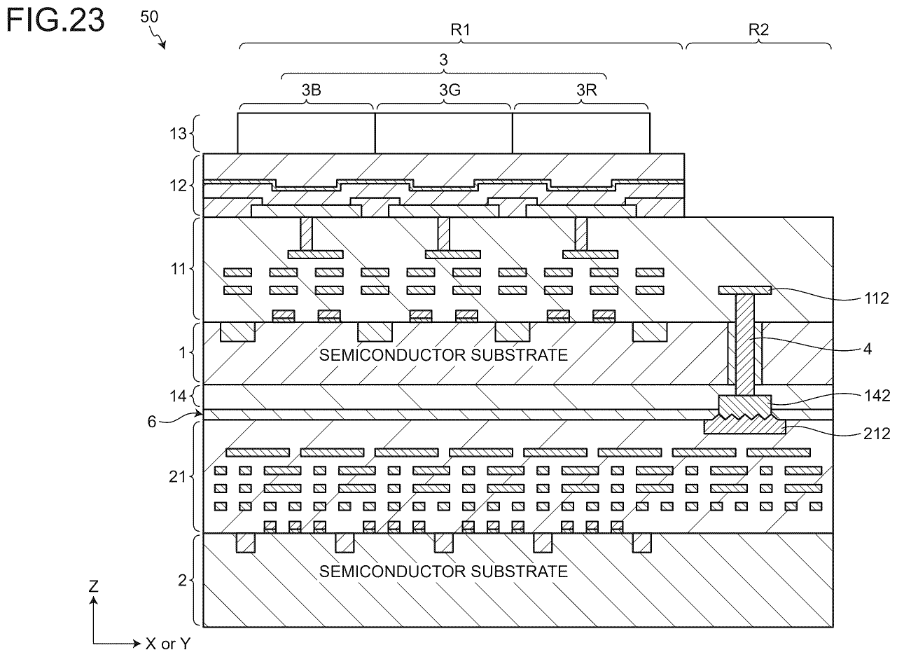

In one embodiment, an insulating thin film may be provided between the back surface wiring layer 14 of the semiconductor substrate 1 and the front surface wiring layer 21 of the semiconductor substrate 2. This will be described with reference to FIG. 23.

FIG. 23 is a diagram illustrating a modification of a semiconductor device. The semiconductor device 50 includes an insulating thin film 6. The insulating thin film 6 is provided between the back surface wiring layer 14 of the semiconductor substrate 1 and the front surface wiring layer 21 of the semiconductor substrate 2 (portion of the bonding surface). This improves the reliability of bonding. For example, the reason is as follows, and further details are disclosed in Patent Literature 3.

In the semiconductor device 50, positional displacement, a shape, a size difference, and the like of the wiring 142 and the wiring 212 to be joined may occur. As a result, a joining surface between a portion other than the wiring 142 in the back surface wiring layer 14 and the wiring 212 is generated, or a joining surface between a portion other than the wiring 212 in the front surface wiring layer 21 and the wiring 142 is generated. If there is such an undesired joining surface, a void is generated there, the strength of bonding is reduced, and there may be a problem that the semiconductor substrate 1 and the semiconductor substrate 2 are easily peeled off. By providing the insulating thin film 6, the generation of an undesired joining surface can be suppressed, and the reliability of bonding of the back surface wiring layer 14 of the semiconductor substrate 1 and the front surface wiring layer 21 of the semiconductor substrate 2 can be improved.

For example, in a case where the wiring interlayer film on the joining surface is a TEOS film, a void due to dehydration condensation is generated on the joining surface because many OH groups are present on the surface. By providing the insulating thin film 6 on the joining surface, there is no TEOS joining.

An example of the insulating thin film 6 is an oxide film of SiO2, HfO2, or the like. A nitride film may be used, and it is possible to suppress leakage occurring between the semiconductor substrate 1 and the semiconductor substrate 2 or in the same substrate via the joining surface. A stacked structure of an oxide film and a nitride film may be used.

The insulating thin film 6 may be provided on the entire surface of the joining surface. The joining strength is easily increased, and the possibility that leakage between the semiconductor substrate 1 and the semiconductor substrate 2 can be suppressed is increased. It is also possible to lower the resistance between the electrodes by deforming and breaking only between the electrodes on the bonding surface.

The insulating thin film 6 is provided on the joining surface before the back surface wiring layer 14 of the semiconductor substrate 1 and the front surface wiring layer 21 of the semiconductor substrate 2 are bonded together. The insulating thin film 6 may be provided on both the semiconductor substrate 1 and the semiconductor substrate 2, or may be provided only on one of the semiconductor substrate 1 and the semiconductor substrate 2.

Deformation and breakdown of the insulating thin film 6 between the wiring 142 and the wiring 212 may be realized by growing crystal grains of Cu of the electrode material by heat treatment. By using this method, it is possible to lower the resistance at the portion where the electrodes are joined to each other while maintaining high insulation at the portion other than the electrode.

When the insulating thin film 6 is thinner, the insulating thin film 6 is more likely to be deformed and broken due to the growth of crystal grains, and the electrodes are more likely to be electrically connected to each other. When the atomic layer deposition (ALD) is used, the extremely thin insulating thin film 6 can be uniformly deposited with good controllability. In addition, in order to grow crystal grains at the time of heat treatment, it is desirable not to grow crystal grains at the time of depositing the insulating thin film 6, and in this respect, the ALD method may be capable of depositing a film at a low temperature (for example, 500° C. or lower). In addition, it is preferable that there is no step or the like in order to uniformly form the extremely thin insulating thin film 6, and it is desirable that the surface on which the insulating thin film 6 is formed be flat. This can be realized by planarizing the joining surface by CMP.

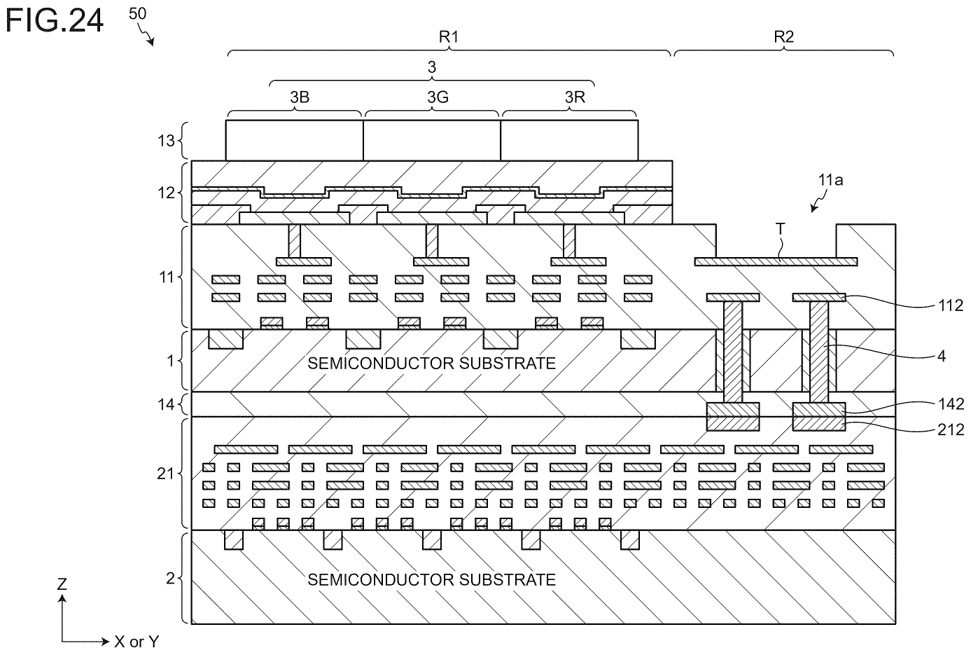

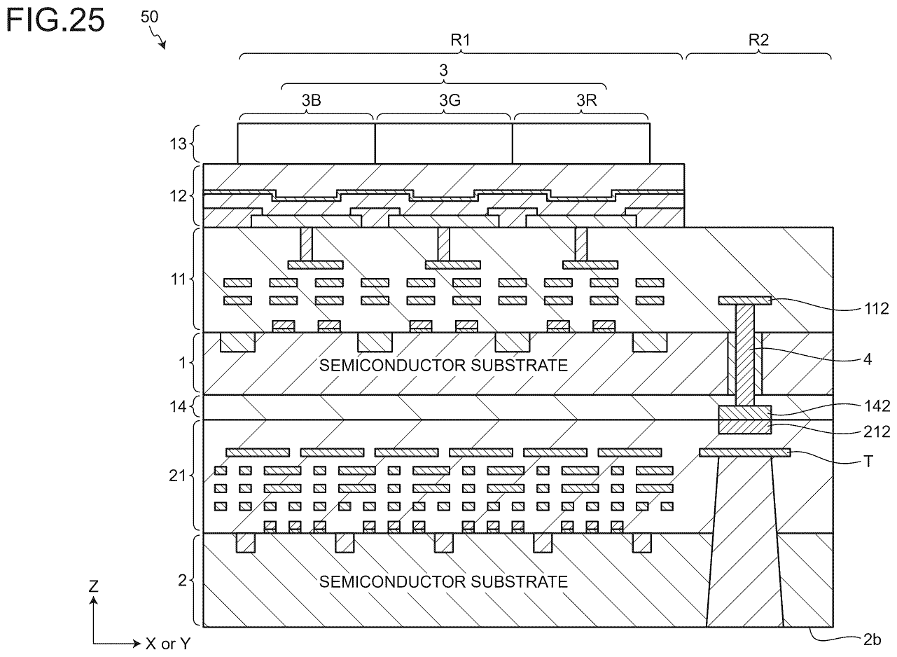

In one embodiment, a pad terminal providing an electrical connection with the outside may be provided. This will be described with reference to FIGS. 24 and 25.

FIG. 24 is a diagram illustrating a modification of a semiconductor device. A recess 11a is provided in the front surface wiring layer 11 of the semiconductor substrate 1. The recess 11a is a portion (pad portion) provided so as to have a step from the upper surface (the surface on the Z-axis positive direction side) of the front surface wiring layer 11. The pad terminal T is provided on the recess 11a. In this example, the pad terminal T is provided on the bottom surface of the recess 11a. The pad terminal T provides electrical connection with the outside of the semiconductor device 50, and is used, for example, for power supply, signal input, and the like, or used for signal output to the outside, and the like. The pad terminal T may be one of the wirings 112 of the front surface wiring layer 11.

If the pad terminal T is provided on the front surface wiring layer 21 of the semiconductor substrate 2, it is necessary to provide the recess 11a through the semiconductor substrate 1 to the semiconductor substrate 2, and the difficulty of the processing process increases. In addition, since the main body 10 of the semiconductor substrate 1 is exposed on the side wall of the recess 11a, it is also necessary to form an insulating film at that portion. The step of the recess 11a also increases. A flexible substrate or the like is joined to the pad terminal T using, for example, an anisotropic conductive film (ACF: thermosetting resin mixed with fine metal particles). At that time, it is necessary to make metal particles larger than the step of the recess 11a, which is disadvantageous for miniaturization of the recess 11a. As illustrated in FIG. 24, the step can be reduced by providing the recess 11a in the semiconductor substrate 1.

Note that, in a case where downsizing of the semiconductor substrate 1 (chip) and maximization of the angle of view are impaired by providing the recess 11a on the front surface side (Z-axis positive direction side), the configuration of FIG. 25 described below may be adopted.

FIG. 25 is a diagram illustrating a modification of a semiconductor device. In this example, the pad terminal T is provided in the front surface wiring layer 21 of the semiconductor substrate 2. The pad terminal T may be one of the wirings 212 of the front surface wiring layer 21. The pad terminal T is accessed from the back surface 2b side of the semiconductor substrate 2 via a via penetrating the semiconductor substrate 2 and a via provided in the front surface wiring layer 21. For example, there is a possibility that the device can be downsized or the angle of view can be increased as compared with the case where the pad terminal T is provided in the front surface wiring layer 11.

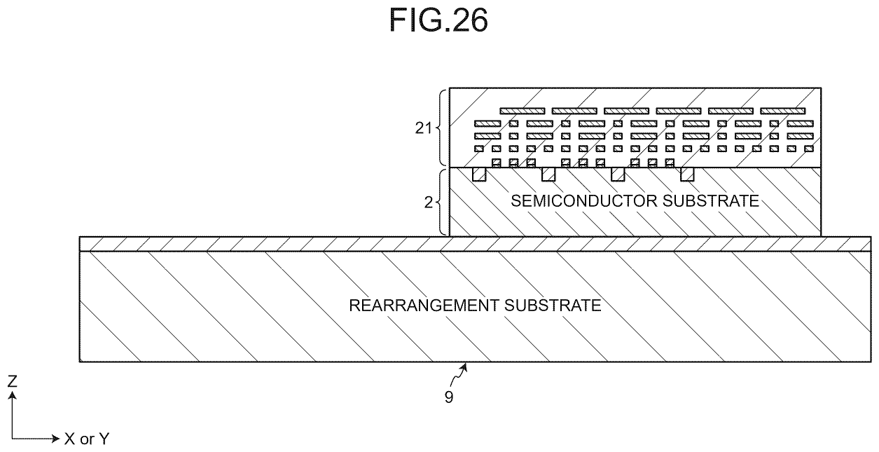

A method for manufacturing the semiconductor device 50 in the case of bonding the back surface wiring layer 14 of the semiconductor substrate 1 in the wafer state and the front surface wiring layer 21 of the semiconductor substrate 2 in the chip state as in FIGS. 19 and 20 described above will be described with reference to FIGS. 26 to 32.

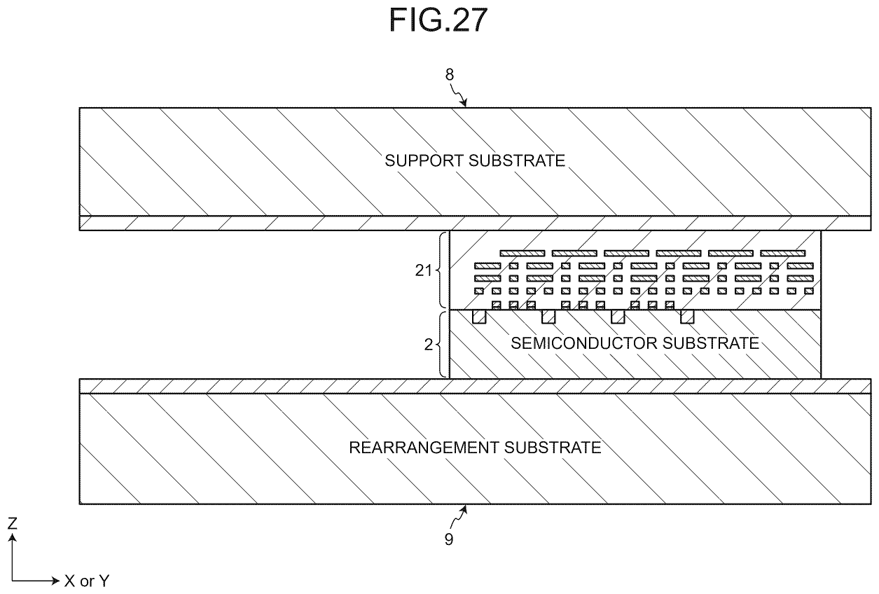

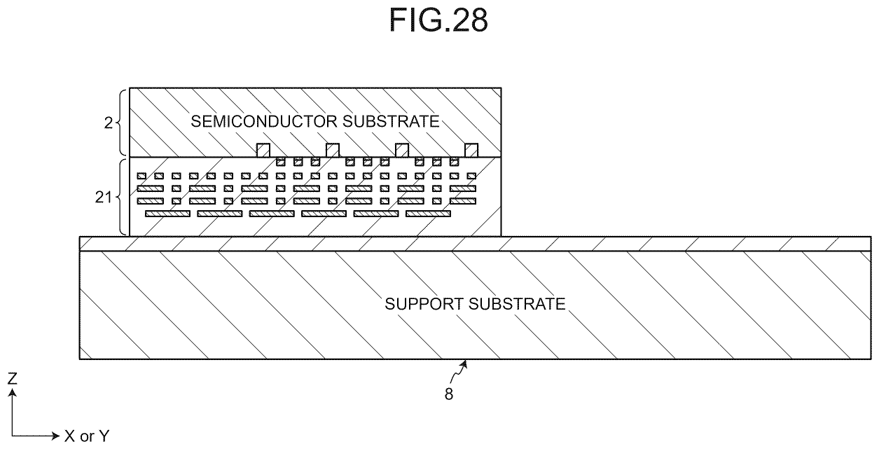

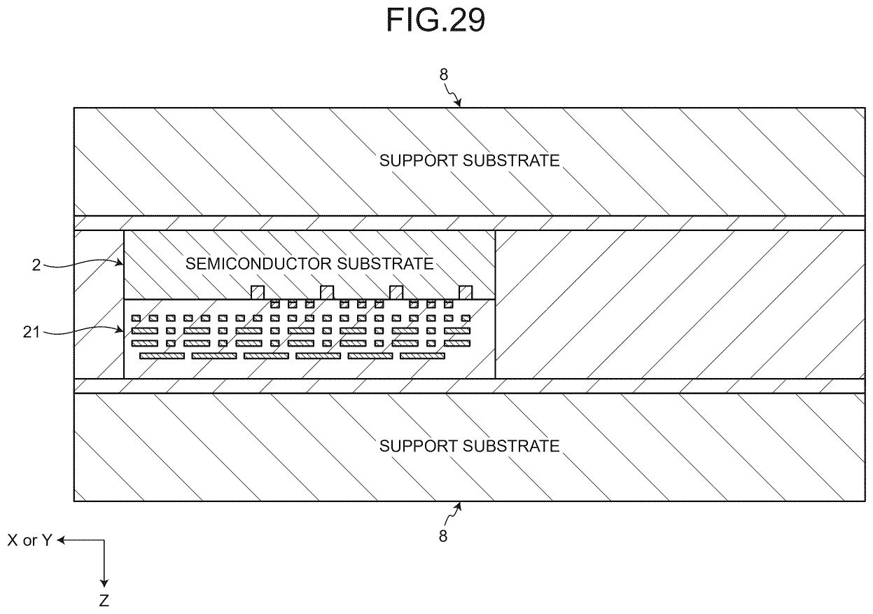

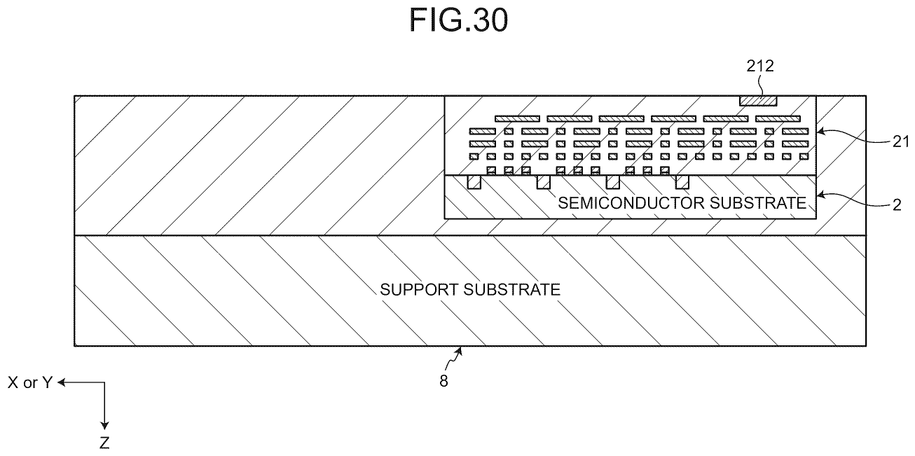

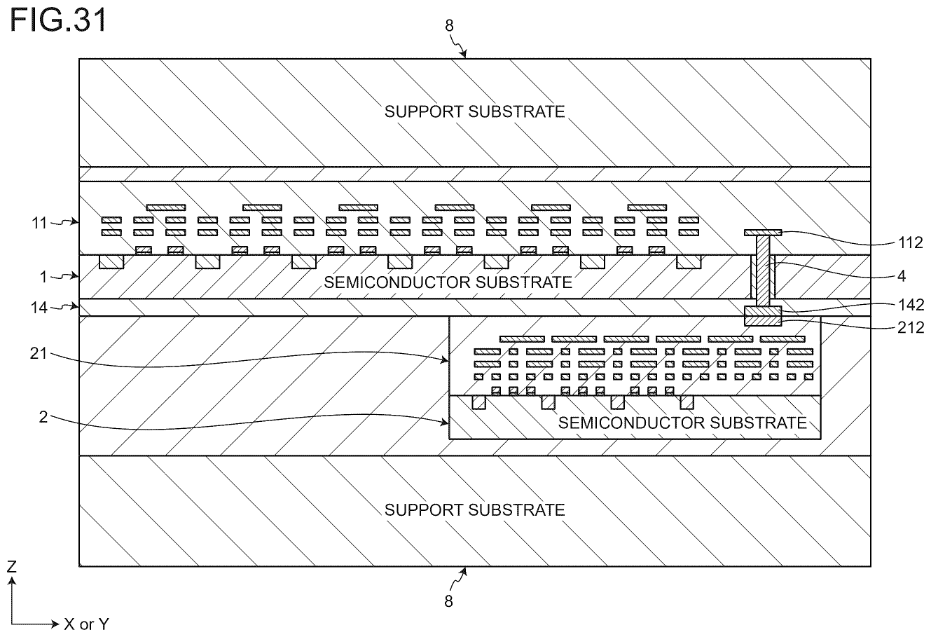

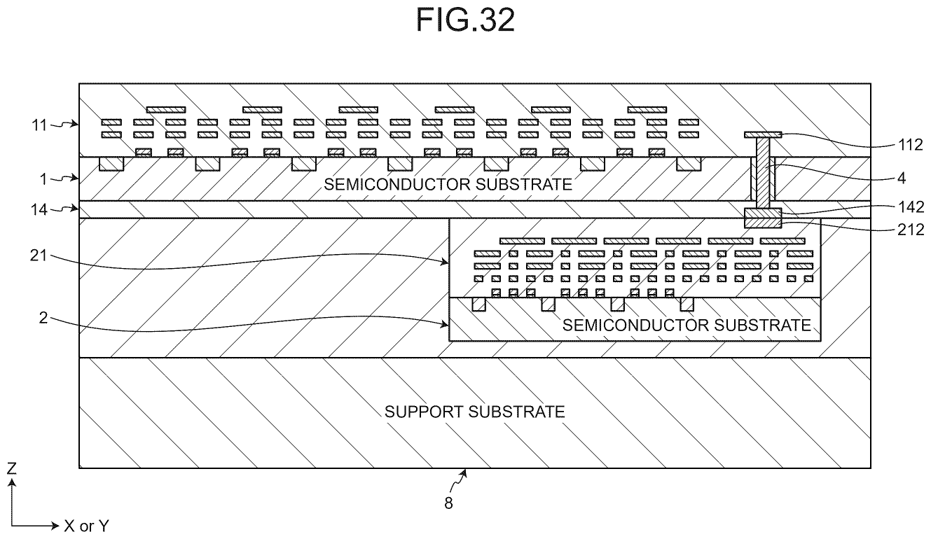

FIGS. 26 to 32 is diagrams illustrating an example of a method for manufacturing a semiconductor device. Details are disclosed in Patent Literature 4, and thus, will be briefly described below. It is assumed that the semiconductor substrate 2 is singulated and electrically inspected to confirm that the semiconductor substrate 2 is a non-defective chip (KGD). As illustrated in FIG. 26, the semiconductor substrate 2 in a chip state is disposed on the rearrangement substrate 9 using, for example, an adhesive. Here, the semiconductor substrate 2 is disposed in alignment with the semiconductor substrate 1. As illustrated in FIG. 27, for example, an interlayer oxide film of the semiconductor substrate 2 is joined to the support substrate 8 provided with an oxide film. As illustrated in FIG. 28, the rearrangement substrate 9 is removed. As illustrated in FIG. 29, after an oxide film is disposed and CMP planarization is performed, the support substrate 8 is joined again. As illustrated in FIG. 30, one support substrate 8 is removed, and the wiring 212 for joining is provided. As illustrated in FIG. 31, the back surface wiring layer 14 of the semiconductor substrate 1 and the front surface wiring layer 21 of the semiconductor substrate 2 are bonded together. As illustrated in FIG. 32, the support substrate 8 of the semiconductor substrate 1 is removed. Thereafter, the light emitting element layer 12 is formed on the front surface wiring layer 11 of the semiconductor substrate 1.

For example, the semiconductor device 50 can be manufactured as described above.

### 3. Example of Effect

The technology described above is specified as follows, for example. One of the disclosed technologies is the semiconductor device 50. As described with reference to FIGS. 1 to 6 and the like, the semiconductor device 50 includes the plurality of pixels 3 each emitting light. The semiconductor device 50 includes the semiconductor substrate 1 (first semiconductor substrate), the front surface wiring layer 11, the light emitting element layer 12, the back surface wiring layer 14, the semiconductor substrate 2 (second semiconductor substrate), the front surface wiring layer 21, and the through-substrate via 4. The semiconductor substrate 1 includes a transistor of the pixel circuit that controls light emission of each of the plurality of pixels 3. The front surface wiring layer 11 is provided on the front surface 1a of the semiconductor substrate 1. The light emitting element layer 12 is provided on the side opposite to the semiconductor substrate 1 with the front surface wiring layer 11 interposed therebetween. The back surface wiring layer 14 is provided on the back surface 1b of the semiconductor substrate 1. The semiconductor substrate 2 includes a transistor of the drive circuit that drives the pixel circuit. The front surface wiring layer 21 is provided on the front surface 2a of the semiconductor substrate 2, and is bonded to the back surface wiring layer 14 of the semiconductor substrate 1 so as to have electrical contact with the back surface wiring layer 14 of the semiconductor substrate 1. The through-substrate via 4 penetrates the semiconductor substrate 1 and connects the front surface wiring layer 11 and the back surface wiring layer 14 of the semiconductor substrate 1.

According to the above semiconductor device 50, not only the front surface wiring layer 11 is provided on the front surface 1a of the semiconductor substrate 1, but also the back surface wiring layer 14 is provided on the back surface 1b of the semiconductor substrate 1. This makes it possible to secure the wiring region while providing the through-substrate via 4.

As described with reference to FIGS. 3 to 5 and the like, the elements of the pixel circuit may be provided over the front surface wiring layer 11 of the semiconductor substrate 1 and the back surface wiring layer 14 of the semiconductor substrate 1. As a result, more wiring regions can be utilized than when only the front surface wiring layer 11 is used. Accordingly, for example, the wiring resistance can be reduced or an area for forming a capacitive element can be secured.

As described with reference to FIGS. 1, 3 to 5, and the like, the semiconductor device 50 may include the display region R1 in which the plurality of pixels 3 is provided, and the non-display region R2 located outside the display region R1 in plan view (when viewed in the Z-axis direction), and the through-substrate via 4 may be provided in at least the non-display region R2 of the display region R1 and the non-display region R2. This makes it easy to secure the wiring region of the display region R1.

As described with reference to FIG. 4 and the like, the through-substrate via 4 may be provided in both the display region R1 and the non-display region R2, and the through-substrate via 4 may be provided for each pixel 3 in the display region R1. By providing the through-substrate via 4 also in the display region R1, the possibility is increased that the front surface wiring layer 11 and the back surface wiring layer 14 can be connected more efficiently.

As described with reference to FIGS. 5 and 6 and the like, the light emitting element layer 12 may include the cathode film 123 provided in common over the plurality of pixels 3, and the back surface wiring layer 14 of the semiconductor substrate 1 may include the wiring 142 connected to the cathode film 123 so as to have the same potential as the cathode film 123. For example, such cathode wiring can be provided in the back surface wiring layer 14.

As described with reference to FIGS. 5 and 6 and the like, the semiconductor device 50 may include the cathode electrode 123a connected to the cathode film 123 and provided on the front surface wiring layer 11 of the semiconductor substrate 1 so as to surround the display region R1 in which the plurality of pixels 3 is provided, and the back surface wiring layer 14 of the semiconductor substrate 1 may include the wiring 142 connected to the cathode electrode 123a so as to have the same potential as the cathode electrode 123a and having a planar shape spreading over the entire display region R1. As a result, the electrical connection of the entire cathode electrode 123a can be strengthened. For example, the influence of the voltage drop appearing in the cathode electrode 123a can be reduced, and the luminance of each pixel 3 in the display region R1 can be made uniform. The frame narrowing is possible.

As described with reference to FIGS. 5, 6, 13, 14, and the like, the through-substrate via 4 may overlap the cathode electrode 123a in plan view (when viewed in the Z-axis direction). As a result, for example, the non-display region R2 can be made as narrow as possible, and the semiconductor device 50 can be further downsized.

As described with reference to FIGS. 15 and 16 and the like, the back surface wiring layer 14 of the semiconductor substrate 1 may be a multilayer wiring layer. As a result, both a wiring pattern suitable for joining and an arbitrary wiring pattern can be obtained.

As described with reference to FIG. 17 and the like, the joined wiring of the wiring 142 of the back surface wiring layer 14 of the semiconductor substrate 1 and the wiring 212 of the front surface wiring layer 21 of the semiconductor substrate 2 may include the low-voltage wiring L_{Low} and the high-voltage wiring L_{High} disposed at the same wiring pitch. Advantages such as facilitation of design are obtained.

At least one of the semiconductor substrate 1 and the semiconductor substrate 2 may contain silicon. As a result, the possibility that the most advanced semiconductor process can be applied is increased, and high integration, high speed, and low power consumption are easily realized.

As described with reference to FIG. 20 and the like, the semiconductor device 50 may include the chip 5 provided on the side opposite to the semiconductor substrate 2 with the semiconductor substrate 1 interposed therebetween. As a result, multi-functionalization of the semiconductor device 50 can be achieved.

The transistor provided on the semiconductor substrate 1 and the transistor provided on the semiconductor substrate 2 may operate at different power supply voltages. As a result, the manufacturing process of each substrate can be simplified.

As described with reference to FIG. 21 and the like, the front surface wiring layer 11 of the semiconductor substrate 1 may also include the transistor of the pixel circuit. As a result, the degree of freedom of the pixel circuit layout can be improved.

As described with reference to FIG. 23 and the like, the semiconductor device 50 may include the insulating thin film 6 provided between the back surface wiring layer 14 of the semiconductor substrate 1 and the front surface wiring layer 21 of the semiconductor substrate 2. As a result, the reliability of bonding of the back surface wiring layer 14 and the front surface wiring layer 21 can be improved.

As described with reference to FIG. 24 and the like, the front surface wiring layer 11 of the semiconductor substrate 1 may include the recess 11a provided with the pad terminal T that provides electrical connection with the outside of the semiconductor device 50. As a result, for example, the step of the recess 11a can be reduced as compared with a case where the recess 11a is provided through the semiconductor substrate 1 to the semiconductor substrate 2.

As described with reference to FIG. 25 and the like, the front surface wiring layer 21 of the semiconductor substrate 2 may include the pad terminal T that provides electrical connection with the outside of the semiconductor device 50. In a case where the downsizing of the semiconductor substrate 1 (chip) and the maximization of the angle of view are impaired when the recess 11a is provided in the front surface wiring layer 11, it is possible to avoid such a case.

As described with reference to FIG. 1 and the like, the light emitting element layer 12 may include the organic film 122 that is provided in common for each pixel 3 and emits white light, and the semiconductor device 50 may include the filter layer 13 that is provided on the opposite side of the front surface wiring layer 11 of the semiconductor substrate 1 with the light emitting element layer 12 interposed therebetween and passes the light of the color of the corresponding pixel 3 among the white light from the light emitting element layer 12. For example, in this manner, the semiconductor device 50 that emits light of a color corresponding to the pixel 3 can be obtained. Alternatively, as described with reference to FIG. 22 and the like, the light emitting element layer 12 may be provided for each pixel 3 and include the organic film 122 that emits light of the color of the corresponding pixel 3. For example, when the organic film 122 of each pixel 3 has a single layer structure, low-voltage operation can be performed. There is also an advantage that the filter layer 13 can be unnecessary.

The manufacturing method described with reference to FIGS. 7 to 12 and the like is also one of the disclosed technologies. A manufacturing method is a method for manufacturing the semiconductor device 50 including the plurality of pixels 3 each emitting light, the method includes: a step (FIG. 7) of preparing the semiconductor substrate 1 (first semiconductor substrate) including the transistor of the pixel circuit that controls light emission of each of the plurality of pixels 3 and provided with the front surface wiring layer 11 on the front surface 1a; a step (FIG. 10) of providing the back surface wiring layer 14 on the back surface 1b of the semiconductor substrate 1 and providing the through-substrate via 4 penetrating the semiconductor substrate 1 and connecting the front surface wiring layer 11 and the back surface wiring layer 14 of the semiconductor substrate 1; and a step (FIG. 11) of bonding the back surface wiring layer 14 of the semiconductor substrate 1 and the front surface wiring layer 21 of the semiconductor substrate 2 including the transistor of the drive circuit that drives the pixel circuit and provided with the front surface wiring layer 21 on the front surface 2a so as to have electrical contact with each other. For example, the semiconductor device 50 described above can be obtained by such a manufacturing method.

As described with reference to FIGS. 26 to 32 and the like, in the bonding step, one of the semiconductor substrate 1 and the semiconductor substrate 2 may be in a wafer state and the other may be in a chip state. Even when the sizes of the semiconductor substrate 1 and the semiconductor substrate 2 are different from each other, it is possible to increase the yield of the smaller substrate. For example, the manufacturing cost can be reduced.

Note that, the effects described in the present disclosure are merely examples and are not limited to the disclosed contents. There may be other effects.

### 4. Other Modifications

### <First Modification>

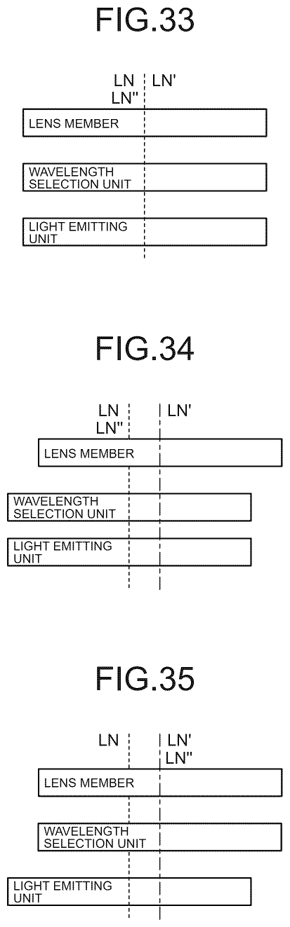

Other modifications will be described. First, with reference to FIGS. 33 to 39, a modification of the relationship among a normal line LN passing through the center of the pixel 3 (hereinafter, it is also referred to as a “sub-pixel”.) , a normal line LN′ passing through the center of a main lens 51 (hereinafter, it is also referred to as a “lens member”.), and a normal line LN″ passing through the center of the filter 13R or the like (hereinafter, it is also referred to as a “wavelength selection unit”.) will be described. FIGS. 33 to 39 are conceptual diagrams for describing a relationship among the normal line LN passing through the center of the sub-pixel, the normal line LN′ passing through the center of the lens member, and the normal line LN″ passing through the center of the wavelength selection unit. Note that, in the following description, the center of the sub-pixel is referred to as the center of a light emitting unit.

The size of the wavelength selection unit may be appropriately changed according to the light emitted from the sub-pixel. A light absorption layer (black matrix layer) may be provided between the wavelength selection units of the sub-pixels that are adjacent to each other. In this case, the size of the light absorption layer may be appropriately changed according to the light emitted from the sub-pixel. Furthermore, the size of the wavelength selection unit may be appropriately changed according to the distance (offset amount) do between the normal line passing through the center of the sub-pixel and the normal line passing through the center of the wavelength selection unit. The planar shape of the wavelength selection unit may be the same as, similar to, or different from the planar shape of the lens member.

For example, as illustrated in FIG. 33, the normal line LN passing through the center of the light emitting unit, the normal line LN″ passing through the center of the wavelength selection unit, and the normal line LN′ passing through the center of the lens member may coincide with each other. In other words, the distance (offset amount) Do between the normal line passing through the center of the light emitting unit and the normal line passing through the center of the lens member and the distance (offset amount) do between the normal line passing through the center of the light emitting unit and the normal line passing through the center of the wavelength selection unit can be equal to 0 (zero).

As illustrated in FIG. 34, the normal line LN passing through the center of the light emitting unit and the normal line LN″ passing through the center of the wavelength selection unit coincide with each other, but the normal line LN passing through the center of the light emitting unit and the normal line LN″ passing through the center of the wavelength selection unit do not need to coincide with the normal line LN′ passing through the center of the lens member. In other words, D₀≠d₀=0 may be satisfied.

As illustrated in FIG. 35, the normal line LN passing through the center of the light emitting unit may not coincide with the normal line LN″ passing through the center of the wavelength selection unit and the normal line LN′ passing through the center of the lens member, and the normal line LN″ passing through the center of the wavelength selection unit and the normal line LN′ passing through the center of the lens member may coincide with each other. In other words, D₀=d₀>0 may be satisfied.

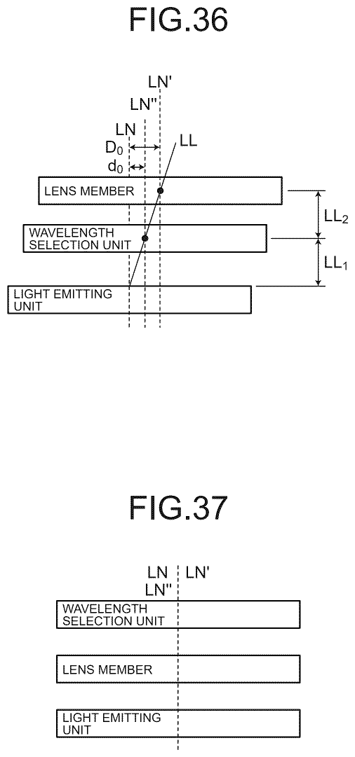

As illustrated in FIG. 36, the normal line LN passing through the center of the light emitting unit may not coincide with the normal line LN″ passing through the center of the wavelength selection unit and the normal line LN′ passing through the center of the lens member, and the normal line LN′ passing through the center of the lens member may not coincide with the normal line LN passing through the center of the light emitting unit and the normal line LN″ passing through the center of the wavelength selection unit. Here, the center of the wavelength selection unit (illustrated with black circles) is preferably located on a straight line LL connecting the center of the light emitting unit and the center of the lens member (illustrated with black circles). Specifically, when a distance from the center of the light emitting unit in the thickness direction to the center of the wavelength selection unit is LL₁, and a distance from the center of the wavelength selection unit in the thickness direction to the center of the lens member is LL₂, D₀>d₀>0 is satisfied, and it is preferable that d₀: D₀=LL₁: (LL₁+LL₂) is satisfied in consideration of manufacturing variations.

The stacking relationship between the wavelength distal end portion and the lens member may be interchanged. In this case, for example, as illustrated in FIG. 37, the normal line LN passing through the center of the light emitting unit, the normal line LN″ passing through the center of the wavelength selection unit, and the normal line LN′ passing through the center of the lens member may coincide with each other. In other words, D₀=d₀=0 may be satisfied.

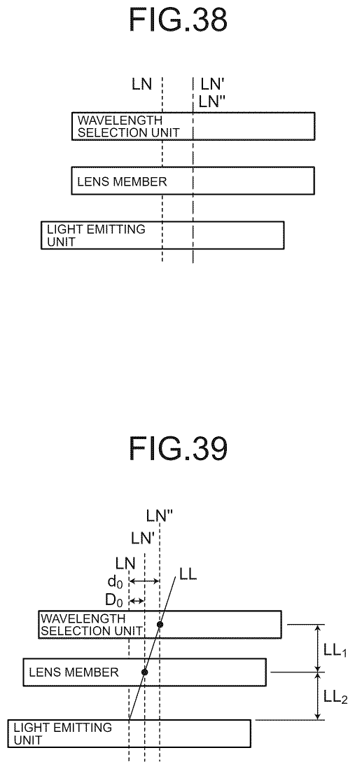

As illustrated in FIG. 38, the normal line LN passing through the center of the light emitting unit may not coincide with the normal line LN″ passing through the center of the wavelength selection unit and the normal line LN′ passing through the center of the lens member, and the normal line LN″ passing through the center of the wavelength selection unit and the normal line LN′ passing through the center of the lens member may coincide with each other. In other words, D₀=d₀>0 may be satisfied.

As illustrated in FIG. 39, the normal line LN passing through the center of the light emitting unit may not coincide with the normal line LN″ passing through the center of the wavelength selection unit and the normal line LN′ passing through the center of the lens member, and the normal line LN′ passing through the center of the lens member may not coincide with the normal line LN passing through the center of the light emitting unit and the normal line LN″ passing through the center of the wavelength selection unit. Here, the center of the wavelength selection unit is preferably located on the straight line LL connecting the center of the light emitting unit and the center of the lens member. Specifically, when a distance from the center of the light emitting unit in the thickness direction to the center of the wavelength selection unit (illustrated with black circles) is LL₁, and a distance from the center of the wavelength selection unit in the thickness direction to the center of the lens member (illustrated with black circles) is LL₂, d₀>D₀>0 is satisfied, and it is preferable that D₀: d₀=LL₂: (LL₁+LL₂) is satisfied in consideration of manufacturing variations.

### <Second Modification>

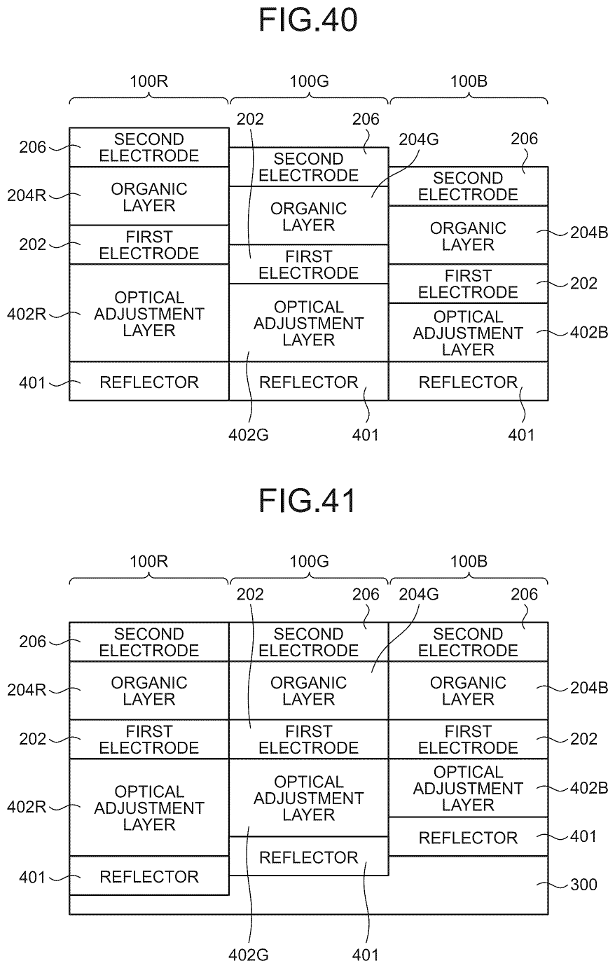

The sub-pixel may have a resonator structure that causes light generated in the light emitting element layer 12 to resonate. This will be described with reference to FIGS. 40 to 46. FIGS. 40 to 46 are schematic cross-sectional diagrams for explaining first to seventh examples of the resonance structure.

Hereinafter, as the sub-pixel, the pixel 3R, the pixel 3G, and the pixel 3B described above will be described as examples. In FIGS. 40 to 46, these pixels are referred to as a sub-pixel 100R, a sub-pixel 100G, and a sub-pixel 100B, respectively in the drawings. The light emitting element layer 12 is an organic material layer of the OLED, and is referred to as an organic layer 204R, an organic layer 204G, and an organic layer 204B in the drawing. The anode electrode 121 described above is referred to as a first electrode 202 in the drawing. The cathode film 123 described above is referred to as a second electrode 206 in the drawing.

### (Resonator Structure: First Example)

FIG. 40 is a schematic cross-sectional diagram for explaining a first example of the resonator structure. In the first example, the first electrode (for example, an anode electrode) 202 is formed with a common film thickness in each sub-pixel. The same applies to the second electrode (for example, a cathode electrode) 206.

As illustrated in FIG. 40, a reflector 401 is below the first electrode 202 of a sub-pixel 100 with an optical adjustment layer 402 interposed therebetween. A resonator structure that resonates light generated by an organic layer (specifically, a light-emitting layer) 204 is formed between the reflector 401 and the second electrode 206.

The reflector 401 is formed with a common film thickness in each sub-pixel 100. The film thicknesses of the optical adjustment layers 402 varies depending on the color to be displayed by the sub-pixel 100. Since optical adjustment layers 402R, 402G, and 402B have different film thicknesses, it is possible to set an optical distance that generates optimum resonance for a wavelength of light corresponding to a color to be displayed.

In the example illustrated in FIG. 40, the upper surfaces of the reflectors 401 in the sub-pixels 100R, 100G, and 100B are disposed so as to be aligned. As described above, since the film thicknesses of the optical adjustment layers 402 varies depending on the color to be displayed by the sub-pixel 100, the positions of the upper surfaces of the second electrodes 206 varies depending on the types of the sub-pixels 100R, 100G, and 100B.

The reflector 401 can be formed using, for example, a metal such as aluminum (Al), silver (Ag), or copper (Cu), or an alloy containing these as main components.

The optical adjustment layer 402 can be made of an inorganic insulating material such as silicon nitride (SiNx), silicon oxide (SiOx), or silicon oxynitride (SiOxNy), or an organic resin material such as an acrylic resin or a polyimide resin. The optical adjustment layer 402 may be a single layer or a stacked film of the plurality of materials. In addition, the number of stacked layers may be different according to the type of the sub-pixel 100.

The first electrode 202 can be formed using, for example, a transparent conductive material such as indium tin oxide (ITO), indium zinc oxide (IZO), or zinc oxide (ZnO).

The second electrode 206 preferably functions as a semi-transmission reflection film. The second electrode 206 can be formed using magnesium (Mg), silver (Ag), a magnesium-silver alloy (MgAg) containing these as main components, an alloy containing an alkali metal or an alkaline earth metal, or the like.

### (Resonator Structure: Second Example)

FIG. 41 is a schematic cross-sectional diagram for explaining a second example of the resonator structure. Also in the second example, the first electrode 202 and the second electrode 206 are formed with a common film thickness in each sub-pixel 100.

Also in the second example, the reflector 401 is disposed below the first electrode 202 of the sub-pixel 100 with the optical adjustment layer 402 interposed therebetween. The resonator structure that resonates light generated by the organic layer 204 is formed between the reflector 401 and the second electrode 206. Similarly to the first example, the reflector 401 is formed with a common film thickness in each sub-pixel 100, and the film thicknesses of the optical adjustment layers 402 varies depending on the color to be displayed by the sub-pixel 100.

In the first example illustrated in FIG. 40, the upper surfaces of the reflectors 401 in the sub-pixels 100R, 100G, and 100B are disposed so as to be aligned, and the positions of the upper surfaces of the second electrodes 206 are different according to the types of the sub-pixels 100R, 100G, and 100B.

On the other hand, in the second example illustrated in FIG. 41, the upper surfaces of the second electrodes 206 are disposed so as to be aligned in the sub-pixels 100R, 100G, and 100B. In order to align the upper surfaces of the second electrodes 206, the upper surfaces of the reflectors 401 in the sub-pixels 100R, 100G, and 100B are disposed differently according to the types of the sub-pixels 100R, 100G, and 100B. Therefore, the lower surfaces of the reflectors 401 have a stair shape according to the types of the sub-pixels 100R, 100G, and 100B.

Materials and the like of which the reflector 401, the optical adjustment layer 402, the first electrode 202, and the second electrode 206 are made, are similar to the contents described in the first example, and thus the description thereof will be omitted.

### (Resonator Structure: Third Example)

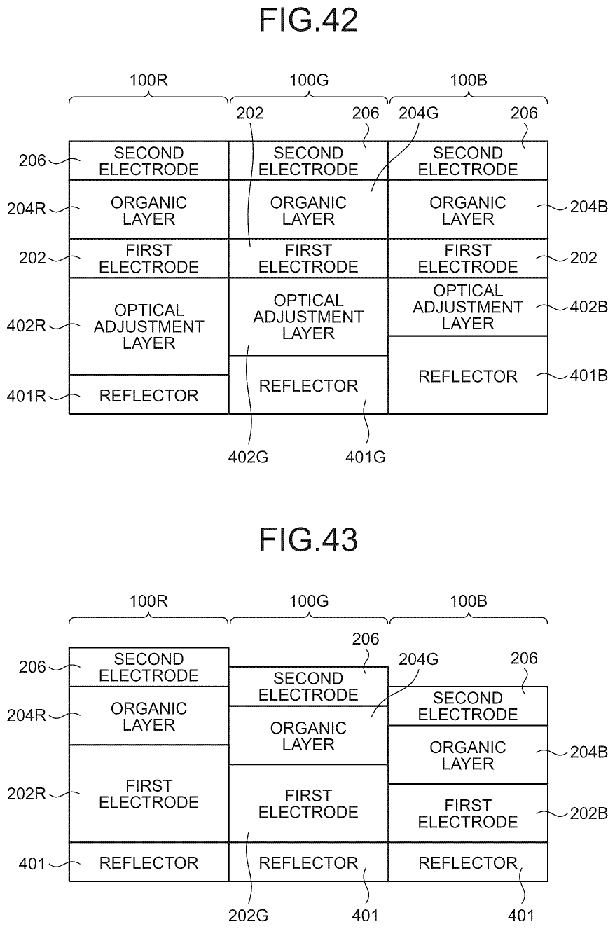

FIG. 42 is a schematic cross-sectional diagram for explaining a third example of the resonator structure. Also in the third example, the first electrode 202 and the second electrode 206 are formed with a common film thickness in each sub-pixel 100.

Also in the third example, the reflector 401 is disposed below the first electrode 202 of the sub-pixel 100 with the optical adjustment layer 402 interposed therebetween. The resonator structure that resonates light generated by the organic layer 204 is formed between the reflector 401 and the second electrode 206. Similarly to the first example and the second example, the film thickness of the optical adjustment layer 402 varies depending on the color to be displayed by the sub-pixel 100. Then, similarly to the second example, the positions of the upper surfaces of the second electrodes 206 are disposed so as to be aligned in the sub-pixels 100R, 100G, and 100B.

In the second example illustrated in FIG. 41, in order to align the upper surfaces of the second electrodes 206, the lower surface of the reflector 401 has a stepped shape according to the types of the sub-pixels 100R, 100G, and 100B.

On the other hand, in the third example illustrated in FIG. 42, the film thickness of the reflector 401 is set to be different according to the types of the sub-pixels 100R, 100G, and 100B. More specifically, the film thickness is set such that the lower surfaces of the reflectors 401R, 401G, and 401B are aligned.

Materials and the like of which the reflector 401, the optical adjustment layer 402, the first electrode 202, and the second electrode 206 are made, are similar to the contents described in the first example, and thus the description thereof will be omitted.

### (Resonator Structure: Fourth Example)

FIG. 43 is a schematic cross-sectional diagram for explaining a fourth example of the resonator structure.

In the first example illustrated in FIG. 40, the first electrode 202 and the second electrode 206 of the sub-pixel 100 are formed with a common film thickness. Then, the reflector 401 is disposed below the first electrode 202 of the sub-pixel 100 with the optical adjustment layer 402 interposed therebetween.

On the other hand, in the fourth example illustrated in FIG. 43, the optical adjustment layer 402 is omitted, and the film thickness of the first electrode 202 is set to be different according to the types of the sub-pixels 100R, 100G, and 100B.

The reflector 401 is formed with a common film thickness in each sub-pixel 100. The film thicknesses of the first electrodes 202 varies depending on the color to be displayed by the sub-pixel 100. Since first electrodes 202R, 202G, and 202B have different film thicknesses, it is possible to set an optical distance that generates optimum resonance for a wavelength of light according to a color to be displayed.

Materials and the like of which the reflector 401, the first electrode 202, and the second electrode 206 are made of, are similar to the contents described in the first example, and thus description thereof will be omitted.

### (Resonator Structure: Fifth Example)

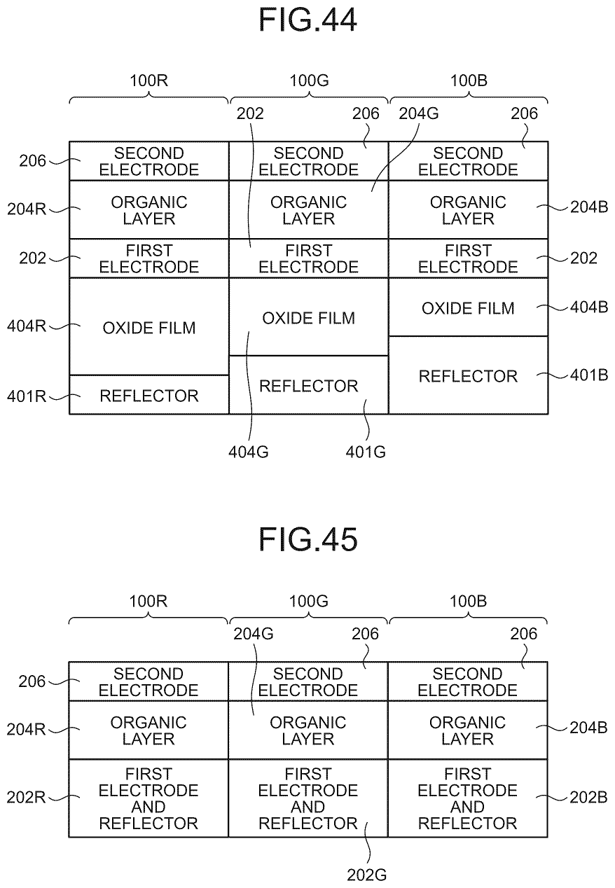

FIG. 44 is a schematic cross-sectional diagram for explaining a fifth example of the resonator structure.

In the first example illustrated in FIG. 40, the first electrode 202 and the second electrode 206 are formed with a common film thickness in each sub-pixel 100. Then, the reflector 401 is disposed below the first electrode 202 of the sub-pixel 100 with the optical adjustment layer 402 interposed therebetween.

On the other hand, in the fifth example illustrated in FIG. 44, the optical adjustment layer 402 is omitted, and instead, an oxide film 404 is formed on the surface of the reflector 401. The film thicknesses of the oxide films 404 are set to be different according to the types of the sub-pixels 100R, 100G, and 100B.

The film thicknesses of the oxide films 404 varies depending on the color to be displayed by the sub-pixel 100. Since oxide films 404R, 404G, and 404B have different film thicknesses, it is possible to set an optical distance that generates optimum resonance for a wavelength of light corresponding to a color to be displayed.

The oxide film 404 is a film obtained by oxidizing the front surface of the reflector 401, and is made of, for example, aluminum oxide, tantalum oxide, titanium oxide, magnesium oxide, zirconium oxide, and the like. The oxide film 404 functions as an insulating film for adjusting an optical path length (optical distance) between the reflector 401 and the second electrode 206.

The oxide films 404 having different film thicknesses according to the types of the sub-pixels 100R, 100G, and 100B can be formed, for example, as follows.

First, electrolytic solution is filled in a container, and a substrate on which the reflector 401 is formed is immersed in the electrolytic solution. In addition, an electrode is disposed so as to face the reflector 401.

Then, positive voltage is applied to the reflector 401 with reference to the electrode, and the reflector 401 is anodized. The film thickness of the oxide film due to the anodic oxidation is proportional to the voltage value with respect to the electrode. Therefore, anodization is performed in a state where the voltage corresponding to the types of the sub-pixels 100R, 100G, and 100B is applied to the reflectors 401R, 401G, and 401B, respectively. As a result, the oxide films 404 having different film thicknesses can be collectively formed.

Materials and the like of which the reflector 401, the first electrode 202, and the second electrode 206 are made of, are similar to the contents described in the first example, and thus description thereof will be omitted.

### (Resonator Structure: Sixth Example)

FIG. 45 is a schematic cross-sectional diagram for explaining a sixth example of the resonator structure. In the sixth example, the sub-pixel 100 is configured by stacking the first electrode 202, the organic layer 204, and the second electrode 206. However, in the sixth example, the first electrode 202 is formed to function as both an electrode and a reflector. The first electrode (and reflector) 202 is made of a material having an optical constant selected according to the types of the sub-pixels 100R, 100G, and 100B. Since the phase shift by the first electrode (and reflector) 202 is different, it is possible to set an optical distance that generates optimum resonance for a wavelength of light according to a color to be displayed.

The first electrode (and reflector) 202 can be made of a single metal such as aluminum (Al), silver (Ag), gold (Au), or copper (Cu), or an alloy containing these as main components.

For example, the first electrode (and reflector) 202R of the sub-pixel 100R can be made of copper (Cu), and the first electrode (also reflector) 202G of the sub-pixel 100G and the first electrode (also reflector) 202B of the sub-pixel 100B can be made of aluminum.

Materials and the like of which the second electrode 206 is made, are similar to the contents described in the first example, and thus the description thereof will be omitted.

### (Resonator Structure: Seventh Example)

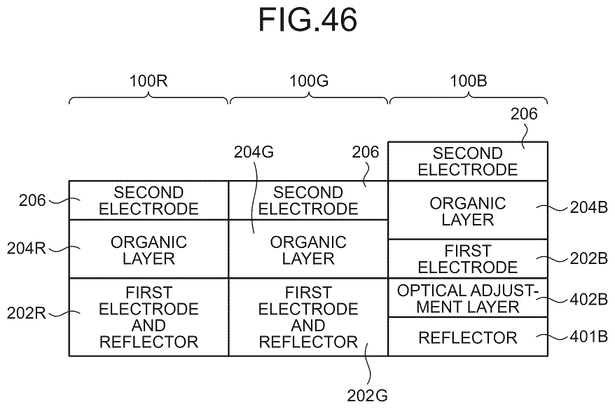

FIG. 46 is a schematic cross-sectional diagram for explaining a seventh example of the resonator structure. In the seventh example, basically, the sixth example is applied to the sub-pixels 100R and 100G, and the first example is applied to the sub-pixel 100B. Also in this configuration, it is possible to set an optical distance that generates optimum resonance for a wavelength of light according to a color to be displayed.

The first electrodes (and reflectors) 202R and 202G used for the sub-pixels 100R and 100G can be made of a single metal such as aluminum (Al), silver (Ag), gold (Au), or copper (Cu), or an alloy containing these as main components.

Materials and the like of which the reflector 401B, the optical adjustment layer 402B, and the first electrode 202B used for the sub-pixel 100B are made, are similar to the contents described in the first example, and thus description thereof will be omitted.

### 5. Application Example

For example, the technology according to the present disclosure may be applied to a display unit or the like of various electronic devices. Therefore, an example of an electronic device to which the present technology can be applied will be described below.

### <First Specific Example>

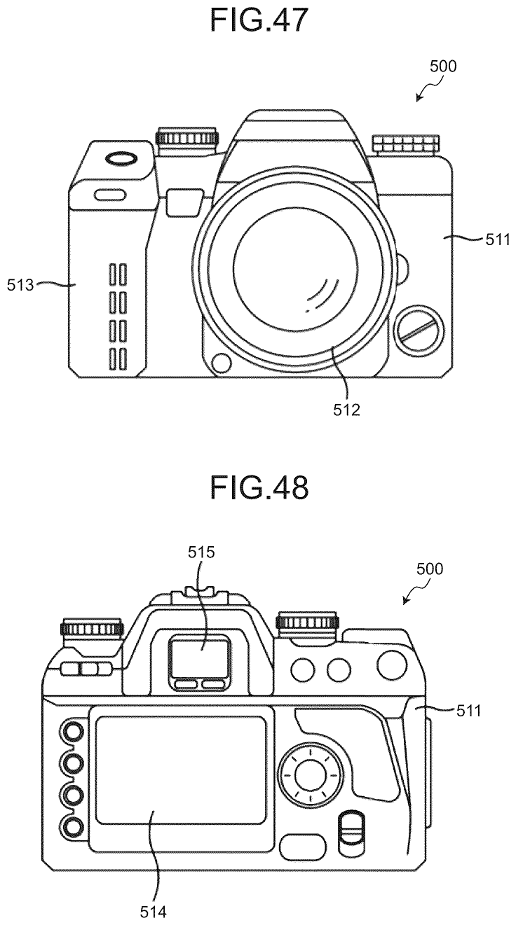

FIG. 47 is a front diagram illustrating an example of an external appearance of a digital still camera 500. FIG. 48 is a rear diagram illustrating an example of an external appearance of the digital still camera 500. The digital still camera 500 is of a lens interchangeable single lens reflex type, and has an interchangeable imaging lens unit (interchangeable lens) 512 substantially at the center of the front of a camera body portion (camera body) 511, and a grip portion 513 to be held by a photographer on the front left side.

A monitor 514 is provided at a position shifted to the left from the center of the back surface of the camera body portion 511. An electronic viewfinder (eyepiece window) 515 is provided above the monitor 514. By looking into the electronic viewfinder 515, a photographer can determine the composition by visually recognizing the optical image of the subject guided from an imaging lens unit 512. As the monitor 514 and the electronic viewfinder 515, the semiconductor device 50 described above can be used.

### <Second Specific Example>

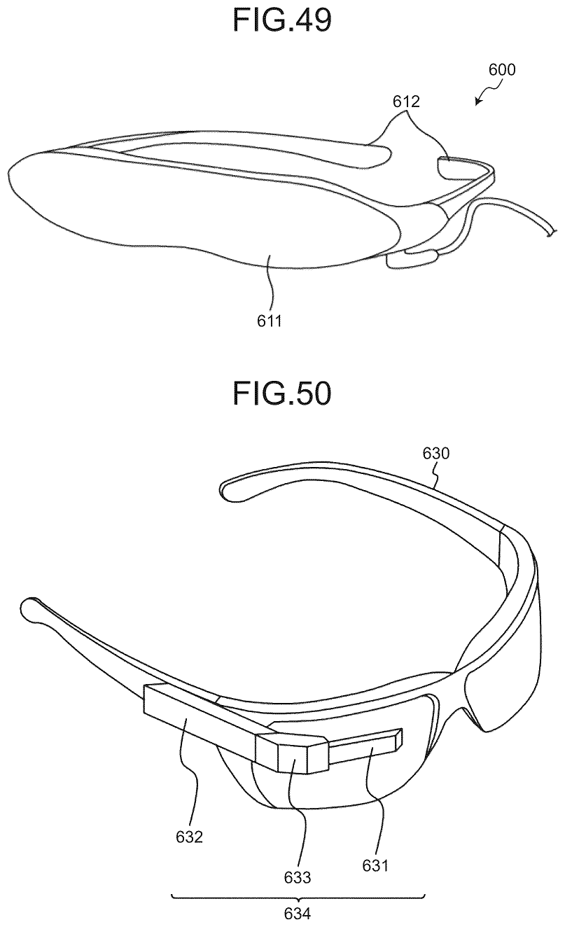

FIG. 49 is an external diagram of a head mounted display 600. The head mounted display 600 includes, for example, ear hooking portions 612 to be worn on the head of a user on both sides of a glass-shaped display portion 611. In the head mounted display 600, the semiconductor device 50 described above can be used as the display portion 611.

### <Third Specific Example>

FIG. 50 is an external diagram of a see-through head mounted display 634. The see-through head mounted display 634 includes a main body 632, an arm 633, and a lens barrel 631.

The main body 632 is connected to the arm 633 and a pair of glasses 630. Specifically, an end portion of the main body 632 in the long side direction is coupled to the arm 633, and one side of the side surface of the main body 632 is coupled to the glasses 630 via a connecting member. Note that, the main body 632 may be directly mounted on the head of the human body.

The main body 632 incorporates a control board for controlling the operation of the see-through head mounted display 634 and a display portion. The arm 633 connects the main body 632 and the lens barrel 631 and supports the lens barrel 631. Specifically, the arm 633 is coupled to the end portion of the main body 632 and the end portion of the lens barrel 631, and fixes the lens barrel 631. In addition, the arm 633 incorporates a signal line for communicating data related to an image provided from the main body 632 to the lens barrel 631.

The lens barrel 631 projects image light provided from the main body 632 via the arm 633 toward the eyes of the user wearing the see-through head mounted display 634 through an eyepiece. In the see-through head mounted display 634, the semiconductor device 50 described above can be used for the display portion of the main body 632.

### <Fourth Specific Example>

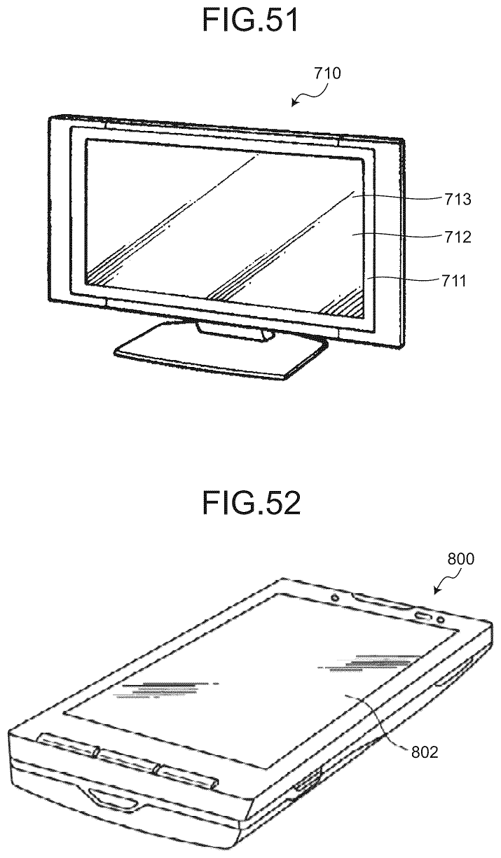

FIG. 51 illustrates an example of an external appearance of a television apparatus 710. The television apparatus 710 includes, for example, a video display screen unit 711 including a front panel 712 and a filter glass 713, and the video display screen unit 711 includes the semiconductor device 50 described above.

### <Fifth Specific Example>

FIG. 52 illustrates an example of an external appearance of a smartphone 800. The smartphone 800 includes a display unit 802 that displays various types of information, an operation unit including a button that receives an operation input by the user, and the like. The display unit 802 can be the semiconductor device 50 described above.

### <Sixth Specific Example>

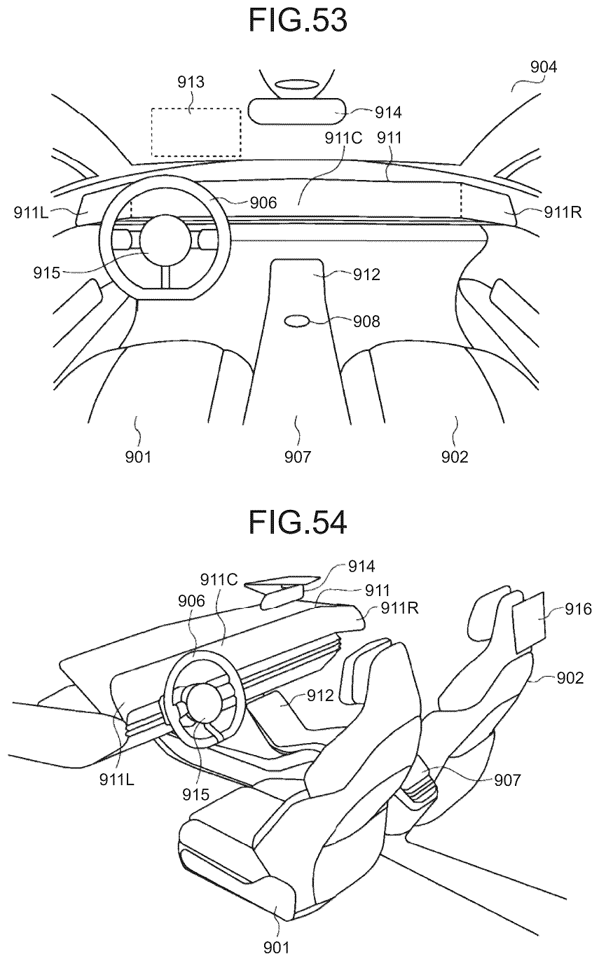

FIGS. 53 and 54 are diagrams illustrating an internal configuration of an automobile including the semiconductor device 50 according to the embodiment of the present disclosure. Specifically, FIG. 59 is a diagram illustrating a state of the inside of the automobile from the rear to the front of the automobile, and FIG. 60 is a diagram illustrating a state of the inside of the automobile from the oblique rear to the oblique front of the automobile.

The automobile illustrated in FIGS. 53 and 54 includes a center display 911, a console display 912, a head-up display 913, a digital rear mirror 914, a steering wheel display 915, and a rear entertainment display 916. The semiconductor device 50 described above can be applied to some or all of these displays.

The center display 911 is disposed on a center console 907 at a position facing a driver's seat 901 and a passenger seat 902. FIGS. 59 and 60 illustrate an example of the center display 911 having a horizontally long shape extending from the driver's seat 901 side to the passenger seat 902 side, but the screen size and the arrangement location of the center display 911 are arbitrary. The center display 911 can display information detected by various sensors (not illustrated). As a specific example, the center display 911 can display a captured image captured by an image sensor, a distance image to an obstacle in front of or on a side of the automobile measured by a time of flight (ToF) sensor, a passenger's body temperature detected by an infrared sensor, and the like. The center display 911 can be used to display, for example, at least one of safety related information, operation related information, a life log, health related information, authentication/identification related information, and entertainment related information.

The safety related information is information such as doze detection, looking-away detection, mischief detection of a child riding together, presence or absence of wearing of a seat belt, and detection of leaving of an occupant, and is information detected by, for example, a sensor (not illustrated) superimposed on the back side of the center display 1911. The operation related information detects a gesture related to the operation of the occupant using the sensor. The detected gesture may include operation of various facilities in the automobile. For example, operations of air conditioner, a navigation device, an audio/visual (AV) device, a lighting device, and the like are detected. The life log includes life logs of all the occupants. For example, the life log includes an action record of each occupant in the automobile. By acquiring and storing the life log, it is possible to confirm the state of the occupant at the time of the accident. The health related information detects the body temperature of the occupant using a temperature sensor, and estimates the health condition of the occupant based on the detected body temperature. Alternatively, the face of the occupant may be imaged using the image sensor, and the health condition of the occupant may be estimated from the imaged facial expression. Furthermore, a conversation may be made with the occupant in an automatic voice, and the health condition of the occupant may be estimated on the basis of the answer content of the occupant. The authentication/identification related information includes a keyless entry function of performing face authentication using a sensor, an automatic adjustment function of a sheet height and a position by face identification, and the like. The entertainment related information includes a function of detecting operation information of the AV device by the occupant using the sensor, a function of recognizing the face of the occupant by the sensor and providing content suitable for the occupant by the AV device, and the like.

The console display 912 can be used to display the life log information, for example. The console display 912 is disposed near a shift lever 908 of the center console 907 between the driver's seat 901 and the passenger seat 902. The console display 912 can also display information detected by various sensors (not illustrated). In addition, the console display 912 may display an image of the periphery of the automobile captured by the image sensor, or may display a distance image to an obstacle in the periphery of the automobile.

The head-up display 913 is virtually displayed behind a windshield 904 in front of the driver's seat 901. The head-up display 913 can be used to display, for example, at least one of safety related information, operation related information, a life log, health related information, authentication/identification related information, and entertainment related information. Since the head-up display 913 is virtually disposed in front of the driver's seat 901 in many cases, the head-up display is suitable for displaying information directly related to the operation of the automobile such as the speed of the automobile and the remaining amount of fuel (battery).

The digital rear mirror 914 can display not only the rear of the automobile but also the state of the occupant in the back seat, and thus can be used to display the life log information, for example, by overlapping a sensor (not illustrated) on the back surface side of the digital rear mirror 914.

The steering wheel display 915 is disposed near the center of a steering wheel 906 of the automobile. The steering wheel display 915 can be used to display, for example, at least one of safety related information, operation related information, a life log, health related information, authentication/identification related information, and entertainment related information. In particular, since the steering wheel display 915 is close to the driver's hand, the steering wheel display is suitable for displaying the life log information such as the body temperature of the driver, or for displaying information related to the operation of the AV device, the air conditioner, or the like.

The rear entertainment display 916 is attached to the back side of the driver's seat 901 and the passenger seat 902, and is for viewing by the occupant in the rear seat. The rear entertainment display 916 can be used to display, for example, at least one of safety related information, operation related information, a life log, health related information, authentication/identification related information, and entertainment related information. In particular, since the rear entertainment display 916 is in front of the occupant in the back seat, information related to the occupant in the back seat is displayed. For example, information related to the operation of the AV device or the air conditioner may be displayed, or a result of measuring the body temperature or the like of the occupant in the back seat by the temperature sensor (not illustrated) may be displayed.

Although the embodiments of the present disclosure have been described above, the technical scope of the present disclosure is not limited to the above-described embodiments as it is, and various modifications can be made without departing from the gist of the present disclosure. In addition, components of different embodiments and modifications may be appropriately combined.

Note that, the present technology can also have the following configurations. (1) A semiconductor device including a plurality of pixels each emitting light, the semiconductor device comprising:
a first semiconductor substrate including a transistor of a pixel circuit configured to control light emission of each of the plurality of pixels;
a front surface wiring layer provided on a front surface of the first semiconductor substrate;
a light emitting element layer provided on a side opposite to the first semiconductor substrate with the front surface wiring layer interposed therebetween;
a back surface wiring layer provided on a back surface of the first semiconductor substrate;
a second semiconductor substrate including a transistor of a drive circuit configured to drive the pixel circuit;
a front surface wiring layer provided on a front surface of the second semiconductor substrate and bonded to the back surface wiring layer of the first semiconductor substrate so as to have electrical contact with the back surface wiring layer of the first semiconductor substrate; and
a through-substrate via configured to penetrate the first semiconductor substrate and connect the front surface wiring layer and the back surface wiring layer of the first semiconductor substrate.

(2) The semiconductor device according to (1), wherein
an element of the pixel circuit is provided over the front surface wiring layer and the back surface wiring layer of the first semiconductor substrate.

(3) The semiconductor device according to (1) or (2), comprising:
a display region in which the plurality of pixels is provided; and
a non-display region located outside the display region in plan view, wherein
the through-substrate via is provided in at least the non-display region of the display region and the non-display region.

(4) The semiconductor device according to (3), wherein
the through-substrate via is provided in both the display region and the non-display region, and
the through-substrate via is provided for each pixel in the display region.

(5) The semiconductor device according to any one of (1) to (4), wherein
the light emitting element layer includes a cathode film provided in common over the plurality of pixels, and
the back surface wiring layer of the first semiconductor substrate includes wiring connected to the cathode film so as to have same potential as the cathode film.

(6) The semiconductor device according to (5), comprising
a cathode electrode connected to the cathode film and provided on the front surface wiring layer of the first semiconductor substrate so as to surround a display region in which the plurality of pixels is provided, wherein
the back surface wiring layer of the first semiconductor substrate includes wiring connected to the cathode electrode so as to have same potential as the cathode electrode and having a planar shape spreading over the entire display region.

(7) The semiconductor device according to (5) or (6), comprising
a cathode electrode connected to the cathode film and provided on the front surface wiring layer of the first semiconductor substrate so as to surround a display region in which the plurality of pixels is provided, wherein
the through-substrate via overlaps with the cathode electrode in plan view.

(8) The semiconductor device according to any one of (1) to (7), wherein
the back surface wiring layer of the first semiconductor substrate is a multilayer wiring layer.

(9) The semiconductor device according to any one of (1) to (8), wherein
joined wiring of wiring of the back surface wiring layer of the first semiconductor substrate and wiring of the front surface wiring layer of the second semiconductor substrate includes low-voltage wiring and high-voltage wiring disposed at same wiring pitch.

(10) The semiconductor device according to any one of (1) to (9), wherein
at least one of the first semiconductor substrate and the second semiconductor substrate contains silicon.

(11) The semiconductor device according to any one of (1) to (10), comprising
a chip provided on a side opposite to the second semiconductor substrate with the first semiconductor substrate interposed therebetween.

(12) The semiconductor device according to any one of (1) to (11), wherein
a transistor provided on the first semiconductor substrate and a transistor provided on the second semiconductor substrate operate at different power supply voltages.

(13) The semiconductor device according to any one of (1) to (12), wherein
the front surface wiring layer of the first semiconductor substrate also includes a transistor of the pixel circuit.

(14) The semiconductor device according to any one of (1) to (13), comprising
an insulating thin film provided between the back surface wiring layer of the first semiconductor substrate and the front surface wiring layer of the second semiconductor substrate.

(15) The semiconductor device according to any one of (1) to (14), wherein
the front surface wiring layer of the first semiconductor substrate includes a recess provided with a pad terminal configured to provide electrical connection with outside of the semiconductor device.

(16) The semiconductor device according to any one of (1) to (14), wherein
the front surface wiring layer of the second semiconductor substrate includes a pad terminal configured to provide electrical connection with outside of the semiconductor device.

(17) The semiconductor device according to any one of (1) to (16), wherein
the light emitting element layer includes an organic film provided in common for each pixel and emitting white light, and
the semiconductor device includes a filter layer provided on a side opposite to the front surface wiring layer of the first semiconductor substrate with the light emitting element layer interposed therebetween and allowing light of a corresponding pixel color among the white light from the light emitting element layer to pass therethrough.

(18) The semiconductor device according to any one of (1) to (16), wherein
the light emitting element layer includes an organic film provided for each pixel and emitting light of a corresponding pixel color.

(19) A method for manufacturing a semiconductor device including a plurality of pixels each emitting light, the method comprising:
a step of preparing a first semiconductor substrate including a transistor of a pixel circuit configured to control light emission of each of the plurality of pixels and provided with a front surface wiring layer on a front surface thereof;
a step of providing a back surface wiring layer on a back surface of the first semiconductor substrate, and providing a through-substrate via penetrating the first semiconductor substrate and connecting the front surface wiring layer and the back surface wiring layer of the first semiconductor substrate; and
a step of bonding the back surface wiring layer of the first semiconductor substrate and a front surface wiring layer of a second semiconductor substrate including a transistor of a drive circuit configured to drive the pixel circuit and provided with the front surface wiring layer on a front surface thereof so as to have electrical contact with each other.

(20) The method for manufacturing the semiconductor device according to (19), wherein
in the bonding step, one of the first semiconductor substrate and the second semiconductor substrate is in a wafer state and the other is in a chip state.

### REFERENCE SIGNS LIST

50 SEMICONDUCTOR DEVICE
1 SEMICONDUCTOR SUBSTRATE (FIRST SEMICONDUCTOR SUBSTRATE)
1a FRONT SURFACE
1b BACK SURFACE
10 MAIN BODY
10a SEPARATION REGION
11 FRONT SURFACE WIRING LAYER
11a RECESS
110 MAIN BODY
111 GATE ELECTRODE
111a INSULATING FILM
112 WIRING
113 VIA
114 GATE ELECTRODE
114a INSULATING FILM
114b SOURCE/DRAIN
12 LIGHT EMITTING ELEMENT LAYER
121 ANODE ELECTRODE
122 ORGANIC FILM
122B ORGANIC FILM
122G ORGANIC FILM
122R ORGANIC FILM
123 CATHODE FILM
123a CATHODE ELECTRODE
124 PROTECTIVE FILM
13 FILTER LAYER
13B FILTER
13G FILTER
13R FILTER
14 BACK SURFACE WIRING LAYER
140 MAIN BODY
142 WIRING
2 SEMICONDUCTOR SUBSTRATE (SECOND SEMICONDUCTOR SUBSTRATE)
2a FRONT SURFACE
2b BACK SURFACE
21 FRONT SURFACE WIRING LAYER
210 MAIN BODY
211 GATE ELECTRODE
211a INSULATING FILM
212 WIRING
3 PIXEL
3B PIXEL
3G PIXEL
3R PIXEL
31 LIGHT EMITTING ELEMENT
33 SCANNING CIRCUIT
34 LIGHT EMISSION CONTROL TRANSISTOR CONTROL CIRCUIT
35 IMAGE SIGNAL OUTPUT CIRCUIT
36 FIRST CURRENT SUPPLY UNIT
37 SECOND CURRENT SUPPLY UNIT
4 THROUGH-SUBSTRATE VIA
4a INSULATING FILM
5 CHIP
6 INSULATING THIN FILM
7 PAD PORTION
8 SUPPORT SUBSTRATE
9 REARRANGEMENT SUBSTRATE
L_{High} HIGH-VOLTAGE WIRING
L_{Low} LOW-VOLTAGE WIRING
P_{High} WIRING PITCH
P_{Low} WIRING PITCH
R1 DISPLAY REGION
R2 NON-DISPLAY REGION
T PAD TERMINAL

1. A semiconductor device including a plurality of pixels each emitting light, the semiconductor device comprising:
a first semiconductor substrate including a transistor of a pixel circuit configured to control light emission of each of the plurality of pixels;
a front surface wiring layer provided on a front surface of the first semiconductor substrate;
a light emitting element layer provided on a side opposite to the first semiconductor substrate with the front surface wiring layer interposed therebetween;
a back surface wiring layer provided on a back surface of the first semiconductor substrate;
a second semiconductor substrate including a transistor of a drive circuit configured to drive the pixel circuit;
a front surface wiring layer provided on a front surface of the second semiconductor substrate and bonded to the back surface wiring layer of the first semiconductor substrate so as to have electrical contact with the back surface wiring layer of the first semiconductor substrate; and
a through-substrate via configured to penetrate the first semiconductor substrate and connect the front surface wiring layer and the back surface wiring layer of the first semiconductor substrate.

2. The semiconductor device according to claim 1, wherein
an element of the pixel circuit is provided over the front surface wiring layer and the back surface wiring layer of the first semiconductor substrate.

3. The semiconductor device according to claim 1, comprising:
a display region in which the plurality of pixels is provided; and
a non-display region located outside the display region in plan view, wherein
the through-substrate via is provided in at least the non-display region of the display region and the non-display region.

4. The semiconductor device according to claim 3, wherein
the through-substrate via is provided in both the display region and the non-display region, and
the through-substrate via is provided for each pixel in the display region.

5. The semiconductor device according to claim 1, wherein
the light emitting element layer includes a cathode film provided in common over the plurality of pixels, and
the back surface wiring layer of the first semiconductor substrate includes wiring connected to the cathode film so as to have same potential as the cathode film.

6. The semiconductor device according to claim 5, comprising
a cathode electrode connected to the cathode film and provided on the front surface wiring layer of the first semiconductor substrate so as to surround a display region in which the plurality of pixels is provided, wherein
the back surface wiring layer of the first semiconductor substrate includes wiring connected to the cathode electrode so as to have same potential as the cathode electrode and having a planar shape spreading over the entire display region.

7. The semiconductor device according to claim 5, comprising
a cathode electrode connected to the cathode film and provided on the front surface wiring layer of the first semiconductor substrate so as to surround a display region in which the plurality of pixels is provided, wherein
the through-substrate via overlaps with the cathode electrode in plan view.

8. The semiconductor device according to claim 1, wherein
the back surface wiring layer of the first semiconductor substrate is a multilayer wiring layer.

9. The semiconductor device according to claim 1, wherein
joined wiring of wiring of the back surface wiring layer of the first semiconductor substrate and wiring of the front surface wiring layer of the second semiconductor substrate includes low-voltage wiring and high-voltage wiring disposed at same wiring pitch.

10. The semiconductor device according to claim 1, wherein
at least one of the first semiconductor substrate and the second semiconductor substrate contains silicon.

11. The semiconductor device according to claim 1, comprising
a chip provided on a side opposite to the second semiconductor substrate with the first semiconductor substrate interposed therebetween.

12. The semiconductor device according to claim 1, wherein
a transistor provided on the first semiconductor substrate and a transistor provided on the second semiconductor substrate operate at different power supply voltages.

13. The semiconductor device according to claim 1, wherein
the front surface wiring layer of the first semiconductor substrate also includes a transistor of the pixel circuit.

14. The semiconductor device according to claim 1, comprising
an insulating thin film provided between the back surface wiring layer of the first semiconductor substrate and the front surface wiring layer of the second semiconductor substrate.

15. The semiconductor device according to claim 1, wherein
the front surface wiring layer of the first semiconductor substrate includes a recess provided with a pad terminal configured to provide electrical connection with outside of the semiconductor device.

16. The semiconductor device according to claim 1, wherein
the front surface wiring layer of the second semiconductor substrate includes a pad terminal configured to provide electrical connection with outside of the semiconductor device.

17. The semiconductor device according to claim 1, wherein
the light emitting element layer includes an organic film provided in common for each pixel and emitting white light, and
the semiconductor device includes a filter layer provided on a side opposite to the front surface wiring layer of the first semiconductor substrate with the light emitting element layer interposed therebetween and allowing light of a corresponding pixel color among the white light from the light emitting element layer to pass therethrough.

18. The semiconductor device according to claim 1, wherein
the light emitting element layer includes an organic film provided for each pixel and emitting light of a corresponding pixel color.

19. A method for manufacturing a semiconductor device including a plurality of pixels each emitting light, the method comprising:
a step of preparing a first semiconductor substrate including a transistor of a pixel circuit configured to control light emission of each of the plurality of pixels and provided with a front surface wiring layer on a front surface thereof;
a step of providing a back surface wiring layer on a back surface of the first semiconductor substrate, and providing a through-substrate via penetrating the first semiconductor substrate and connecting the front surface wiring layer and the back surface wiring layer of the first semiconductor substrate; and
a step of bonding the back surface wiring layer of the first semiconductor substrate and a front surface wiring layer of a second semiconductor substrate including a transistor of a drive circuit configured to drive the pixel circuit and provided with the front surface wiring layer on a front surface thereof so as to have electrical contact with each other.

20. The method for manufacturing the semiconductor device according to claim 19, wherein
in the bonding step, one of the first semiconductor substrate and the second semiconductor substrate is in a wafer state and the other is in a chip state.
